(19) United States
(12) Patent Application Publication
(10) Pub. No.: US 2023/0187584 A1
(43) Pub. Date: Jun. 15, 2023

(54) DISPLAY DEVICE

(71) Applicant: Samsung Display Co., LTD., Yongin-si, Gyeonggi-do (KR)

(72) Inventors: Jin Taek KIM, Yongin-si, Gyeonggi-do (KR); Seung Min LEE, Hwaseong-si (KR); Jung Hwan YI, Seoul (KR); Hee Keun LEE, Suwon-si (KR); Bek Hyun LIM, Hwaseong-si (KR); Kyung Tae CHAE, Hwaseong-si (KR)

(21) Appl. No.: 17/998,352

(22) PCT Filed: Jul. 28, 2020
(86) PCT No.: PCT/KR2020/009900

§ 371 Date: Nov. 9, 2022

(30) Foreign Application Priority Data
May 13, 2020 (KR) 10-2020-0056940

(51) Int. Cl. H01L 33/38; H01L 33/62; H01L 25/075

(52) U.S. Cl. CPC H01L 33/387; H01L 33/62; H01L 25/0753

(57) ABSTRACT

Provided is a display device. The display device comprises: a first substrate; a first electrode and a second electrode arranged spaced apart from each other on the first substrate; a plurality of light-emitting diodes arranged on the first electrode and the second electrode; a plurality of contact electrodes arranged on the first electrode or the second electrode and being in contact with the light-emitting diodes, wherein the contact electrodes comprise a first contact electrode arranged on the first electrode, a second contact electrode arranged on the second electrode, a third contact electrode facing the first contact electrode in a second direction, and a fourth contact electrode facing the second contact electrode in the second direction, and include an electrode connection unit connected to the third contact electrode and the fourth contact electrode and arranged to surround the second contact electrode.

### TECHNICAL FIELD

The disclosure relates to a display device.

### BACKGROUND ART

The importance of display devices has steadily increased with the development of multimedia technology. In response thereto, various types of display devices such as an organic light emitting display (OLED), a liquid crystal display (LCD) and the like have been used.

A display device is a device for displaying an image, and includes a display panel, such as an organic light emitting display panel or a liquid crystal display panel. The light emitting display panel may include light emitting elements, e.g., light emitting diodes (LED), and examples of the light emitting diode include an organic light emitting diode (OLED) using an organic material as a fluorescent material and an inorganic light emitting diode using an inorganic material as a fluorescent material.

### DISCLOSURE

### Technical Problem

Aspects of the disclosure provide a display device having reduced light emission failure of each subpixel and improved luminance per unit area.

It should be noted that aspects of the disclosure are not limited thereto and other aspects, which are not mentioned herein, will be apparent to those of ordinary skill in the art from the following description.

### Technical Solution

According to an embodiment of the disclosure, a display device comprises a first substrate, a first electrode and a second electrode extending in a first direction on the first substrate and spaced apart from each other in a second direction, a plurality of light emitting elements disposed on the first electrode and the second electrode, and a plurality of contact electrodes disposed on the first electrode or the second electrode and contacting the light emitting elements, wherein the contact electrodes comprise a first contact electrode disposed on the first electrode, a second contact electrode disposed on the second electrode, a third contact electrode spaced apart from the second contact electrode in the first direction and facing the first contact electrode in the second direction and a fourth contact electrode spaced apart from the first contact electrode in the first direction and facing the second contact electrode in the second direction and the display device comprise an electrode connection portion connected to the third contact electrode and the fourth contact electrode and surrounding the second contact electrode.

The electrode connection portion may be integrated with the third contact electrode and the fourth contact electrode.

The display device may further comprise a first insulating layer disposed on the first substrate to cover the first electrode and the second electrode and comprising a first opening exposing a portion of an upper surface of the first electrode and a second opening exposing a portion of an upper surface of the second electrode, wherein the light emitting elements may be disposed on the first insulating layer.

The display device may further comprise a second insulating layer disposed on the first insulating layer and the light emitting elements and exposing both ends of each light emitting element and portions of the first insulating layer on which the contact electrodes are disposed.

The first contact electrode, the second contact electrode, the third contact electrode and the fourth contact electrode may be directly disposed on the first insulating layer, and at least a portion of the electrode connection portion may be disposed on the second insulating layer.

The display device may further comprise a third insulating layer covering the first contact electrode and the second contact electrode, wherein at least a portion of each of the third contact electrode, the fourth contact electrode, and the electrode connection portion may be disposed on the third insulating layer.

The light emitting elements may comprise a first light emitting element having an end in contact with the first contact electrode and the other end in contact with the third contact electrode and a second light emitting element having an end in contact with the fourth contact electrode and the other end in contact with the second contact electrode.

The light emitting elements may further comprise a third light emitting element having both ends not in contact with the contact electrodes.

The first contact electrode may cover the first opening to contact the first electrode, the second contact electrode may cover the second opening to contact the second electrode, and the third contact electrode and the fourth contact electrode may be disposed on the first insulating layer not to contact the first electrode and the second electrode.

The electrode connection portion may comprise a first extension portion extending in the first direction and connected to the third contact electrode and a second extension portion extending in the second direction and having a side connected to the first extension portion and the other side connected to the fourth contact electrode, wherein the first extension portion may be spaced apart from a long side of an outer side of the second contact electrode, and the second extension portion may be spaced apart from a short side of the outer side of the second contact electrode.

A distance between the long side of the second contact electrode and the first extension portion of the electrode connection portion may be equal to or smaller than a distance between the second contact electrode and the fourth contact electrode.

The first extension portion of the electrode connection portion partially may overlap the second electrode in a thickness direction.

Each of the contact electrodes may comprise a first portion and a second portion having a smaller width than the first portion, and a distance between the contact electrodes facing each other in the second direction may be greater between the second portions than between the first portions.

According to an embodiment of the disclosure, a display device comprises a first substrate, a first electrode and a second electrode extending in a first direction on the first substrate and spaced apart from each other in a second direction, a first insulating layer disposed on the first substrate and comprising an opening that exposes a portion of the first electrode or the second electrode, a plurality of light emitting elements disposed on the first insulating layer and having both ends disposed on the first electrode and the second electrode, respectively, a plurality of first-type contact electrodes disposed on the first electrode or the second electrode and contacting the light emitting dements and the first electrode or the second electrode, and a second-type contact electrode contacting the light emitting elements and not contacting the first electrode and the second electrode, wherein the second-type contact electrode comprises a plurality of contact portions disposed on the first electrode or the second electrode but spaced apart from the first-type contact electrodes and an electrode connection portion connecting the contact portions, wherein the electrode connection portion is spaced apart from an outer side of any one of the first-type contact electrodes and surrounds the outer side.

The first-type contact electrodes may comprise a first contact electrode disposed on the first electrode and contacting the first electrode through a first opening exposing a portion of an upper surface of the first electrode and a second contact electrode disposed on the second electrode and contacting the second electrode through a second opening exposing a portion of an upper surface of the second electrode, and the second-type contact electrode comprises a first contact portion disposed on the second electrode and spaced apart from the second contact electrode, a second contact portion disposed on the first electrode and spaced apart from the first contact electrode, and a first electrode connection portion connecting the first contact portion and the second contact portion.

The first electrode connection portion may surround an outer side of the second contact electrode.

The light emitting elements may comprise a first light emitting element having an end in contact with the first contact electrode and the other end in contact with the first contact portion and a second light emitting element having an end in contact with the second contact portion and the other end in contact with the second contact electrode.

The first contact portion may face the first contact electrode, the second contact portion may be spaced apart from the first contact electrode in the first direction, the first electrode connection portion may surround an outer side of the first contact electrode, and the second-type contact electrode may further comprise a third contact portion disposed between the second contact electrode and the first contact portion to face the second contact portion, a fourth contact portion spaced apart from the second contact portion in the first direction to face the second contact electrode, and a second electrode connection portion connecting the third contact portion and the fourth contact portion and surrounding the outer side of the second contact electrode.

The display device may further comprise a second insulating layer disposed on the first insulating layer and the light emitting elements and exposing both ends of each light emitting element and portions of the first insulating layer on which the contact electrodes are disposed, wherein the first-type contact electrodes and the contact portions of the second-type contact electrode may be disposed on the same layer.

The electrode connection portion of the second-type contact electrode may be directly disposed on the second insulating layer.

The details of other embodiments are included in the detailed description and the accompanying drawings.

### Advantageous Effects

In a display device according to an embodiment, some of a plurality of light emitting elements in each subpixel are connected in series to each other. Accordingly, luminance per unit subpixel can be improved, and light emission failure of each subpixel can be reduced. In addition, the placement of an electrode connection portion is designed to secure a sufficient area in which the light emitting elements of each subpixel are disposed and to connect the light emitting elements in series. Therefore, even if the area occupied by each subpixel is small, it is possible to improve luminance while maintaining the size of each subpixel.

The effects according to the embodiments are not limited by the contents exemplified above, and more various effects are included in this disclosure.

### DESCRIPTION OF DRAWINGS

FIG. 1 is a schematic plan view of a display device according to an embodiment;

FIG. 2 is a plan view of a pixel of the display device according to the embodiment;

FIG. 3 is a plan view of a subpixel of FIG. 2;

FIG. 4 is a cross-sectional view taken along lines Q1-Q1′ and Q2-Q2′ of FIG. 3;

FIG. 5 is a cross-sectional view taken along line Q3-Q3′ of FIG. 3;

FIG. 6 is a cross-sectional view taken along lines Q4-Q4′ and Q5-Q5′ of FIG. 3;

FIG. 7 is a cross-sectional view taken along line Q6-Q6′ of FIG. 3;

FIG. 8 is a schematic view of a light emitting element according to an embodiment;

FIG. 9 is a plan view of a subpixel of a display device according to another embodiment;

FIG. 10 is a cross-sectional view taken along line Q7-Q7′ of FIG. 9;

FIG. 11 is a plan view of a subpixel of a display device according to another embodiment;

FIG. 12 is a plan view of a subpixel of a display device according to another embodiment;

FIG. 13 is a cross-sectional view taken along line Q8-Q8′ of FIG. 12;

FIG. 14 is a plan view of a subpixel of a display device according to another embodiment;

FIG. 15 is a cross-sectional view taken along line Q9-Q9′ of FIG. 14; and

FIG. 16 schematically illustrates contact electrodes of a display device according to another embodiment.

### MODE FOR INVENTION

The invention will now be more fully hereinafter with reference to the accompanying drawings, in which preferred embodiments of the invention are shown. This invention may however, be embodied in different forms and should not be construed as limited to the embodiments set forth herein. Rather, these embodiments are provided so that this disclosure will be thorough and complete and will fully convey the scope of the invention to those skilled in the art.

It also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. Similarly, the second element could also be termed the first element.

Hereinafter, embodiments will be described with reference to the accompanying drawings.

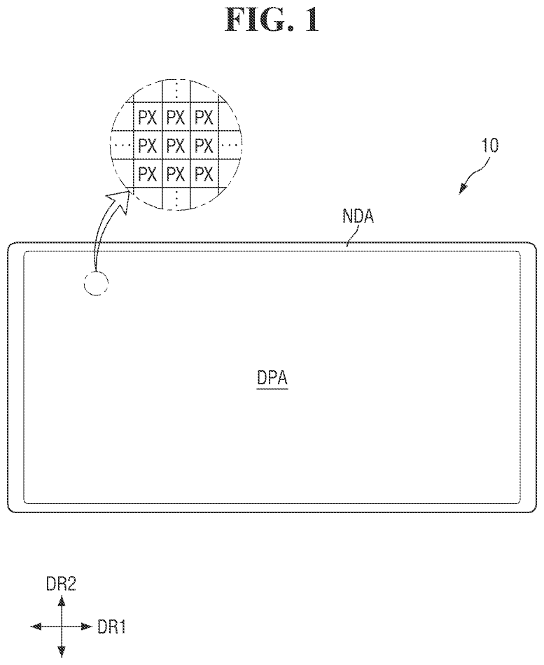

FIG. 1 is a plan view of a display device according to an embodiment.

Referring to FIG. 1, the display device 10 displays moving images or still images. The display device 10 may refer to any electronic device that provides a display screen. Examples of the display device 10 may include televisions, notebook computers, monitors, billboards, the Internet of things (IoT), mobile phones, smartphones, tablet personal computers (PCs), electronic watches, smart watches, watch phones, head mounted displays, mobile communication terminals, electronic notebooks, electronic books, portable multimedia players (PMPs), navigation device, game machines, digital cameras and camcorders, all of which provide a display screen.

The display device 10 includes a display panel that provides a display screen. Examples of the display panel include inorganic light emitting diode display panels, organic light emitting display panels, quantum dot light emitting display panels, plasma display panels, and field emission display panels. A case where an inorganic light emitting diode display panel is applied as an example of the display panel will be described below, but the disclosure is not limited to this case, and other display panels can also be applied as long as the same technical spirit is applicable.

The shape of the display device 10 can be variously modified. For example, the display device 10 may have various shapes such as a horizontally long rectangle, a vertically long rectangle, a square, a quadrilateral with rounded corners (vertices), other polygons, or a circle. The shape of a display area DPA of the display device 10 may also be similar to the overall shape of the display device 10. In FIG. 1, each of the display device 10 and the display area DPA is shaped like a horizontally long rectangle, but the disclosure is not limited thereto.

The display device 10 may include the display area DPA and a non-display area NDA. The display area DPA may be an area where a screen can be displayed, and the non-display area NDA may be an area where no screen is displayed. The display area DPA may also be referred to as an active area, and the non-display area NDA may also be referred to as an inactive area. The display area DA may generally occupy a center of the display device 10.

The display area DA may includes plurality of pixels PX. The pixels PX may be arranged in a matrix direction. Each of the pixels PX may be rectangular or square in plan view. However, the disclosure is not limited thereto, and each of the pixels PX may also have a rhombic planar shape having each side inclined with respect to a direction. The pixels PX may be alternately arranged in a stripe or pentile type. In addition, each of the pixels PX may include one or more light emitting elements 30 which emit light of a specific wavelength band to display a specific color.

The non-display area NDA may be located around the display area DPA. The non-display area NDA may entirely or partially surround the display area DPA. The display area DPA may be rectangular, and the non-display area NDA may be disposed adjacent to four sides of the display area DPA. The non-display area NDA may form a bezel of the display device 10. Wirings or circuit drivers included in the display device 10 may be located, and/or external devices may be mounted, in each non-display area NDA.

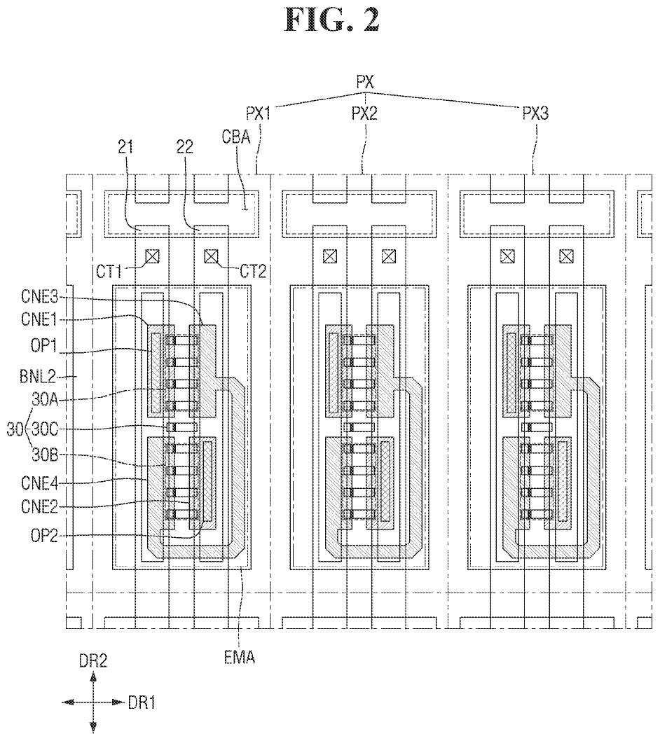

FIG. 2 is a plan view of a pixel of the display device according to the embodiment.

Referring to FIG. 2, each of the pixels PX may include a plurality of subpixels PXn (where n is an integer of 1 to 3). For example, one pixel PX may include a first subpixel PX1, a second subpixel PX2, and a third subpixel PX3. The first subpixel PX1 may emit light of a first color, the second subpixel PX2 may emit light of a second color, and the third subpixel PX3 may emit light of a third color. For example, the first color may be blue, the second color may be green, and the third color may be red. However, the disclosure is not limited thereto, and the subpixels PXn may also emit light of the same color. In addition, although one pixel PX includes three subpixels PXn in FIG. 2, the disclosure is not limited thereto, and the pixel PX may also include additional subpixels PXn.

Each subpixel PXn of the display device 10 may include an emission area EMA and a non-emission area. The emission area EMA may be an area in which the light emitting elements 30 are disposed to emit light of a specific wavelength band. The non-emission area may be an area in which the light emitting elements 30 are not disposed and from which no light is output because light emitted from the light emitting elements 30 does not reach this area. The emission area may include an area where the light emitting elements 30 are located and where light emitted from the light emitting elements 30 is output to an area adjacent to the light emitting elements 30.

However, the disclosure is not limited thereto, and the emission area may also include an area where light emitted from the light emitting elements 30 is output after being reflected or refracted by other members. A plurality of light emitting elements 30 may be disposed in each subpixel PXn, and an area where the light emitting elements 30 are located and an area adjacent to this area may form the emission area.

In addition, each subpixel PXn may include a cutout area CBA disposed in the non-emission area. The cutout area CBA may be disposed on a side of the emission area EMA in a second direction DR2. The cutout area CBA may be disposed between the emission areas EMA of subpixels PXn neighboring in the second direction DR2. A plurality of emission areas EMA and a plurality of cutout areas CBA may be arranged in the display area DPA of the display device 10. For example, the emission areas EMA and the cutout areas CBA may each be repeatedly arranged in a first direction DR1, but may be alternately arranged in the second direction DR2. In addition, a distance between the cutout areas CBA in the first direction DR1 may be smaller than a distance between the emission areas EMA in the first direction DR1. A second bank BNL2 may be disposed between the cutout areas CBA and the emission areas EMA, and a distance between the cutout areas CBA and the emission areas EMA may vary according to a width of the second bank BNL2. Since the light emitting elements 30 are not disposed in the cutout areas CBA, no light is emitted from the cutout areas CBA. However, portions of electrodes 21 and 22 disposed in each subpixel PXn may be disposed in the cutout area CBA. The electrodes 21 and 22 disposed in each subpixel PXn may be separated from those of an adjacent subpixel PXn in the cutout area CBA.

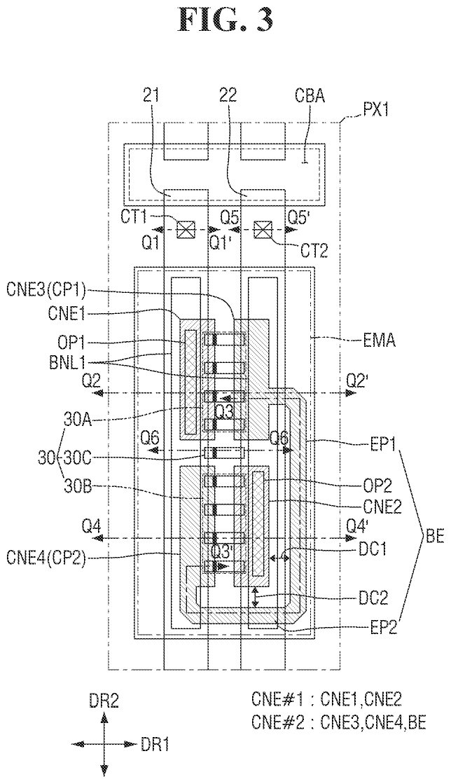

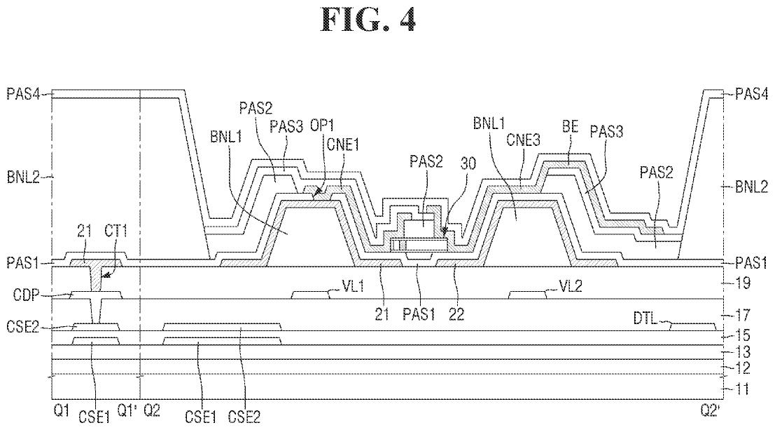

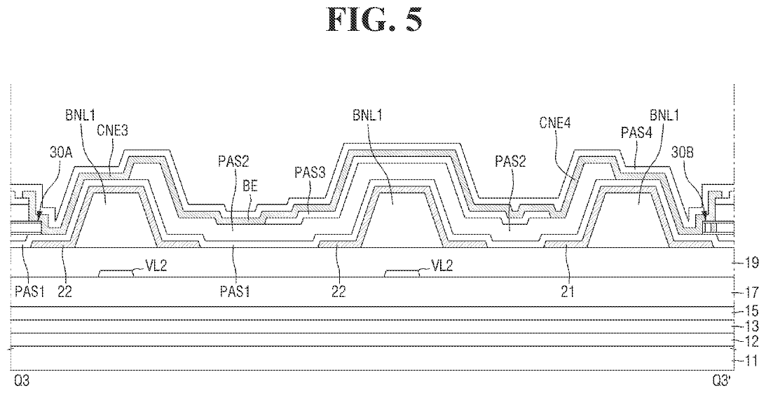

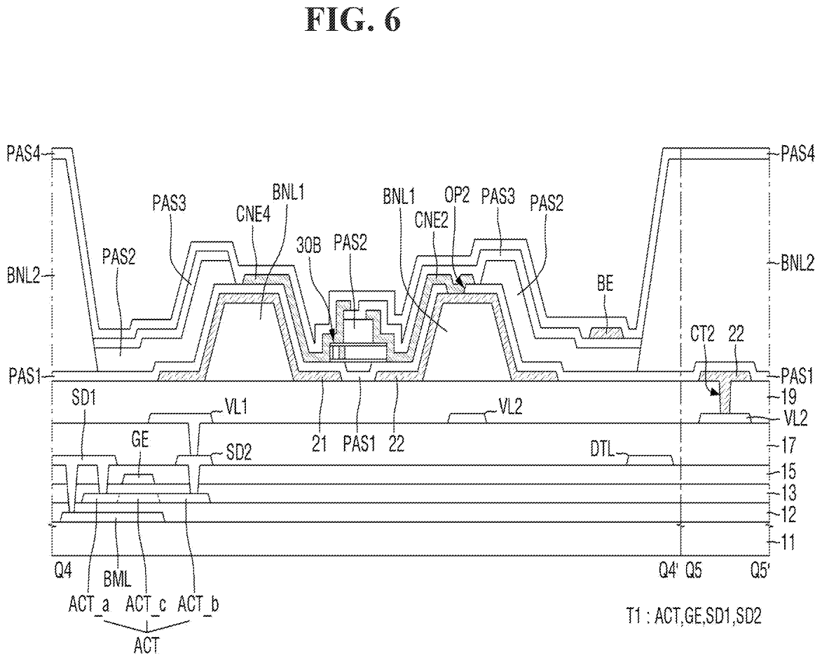

FIG. 3 is a plan view of a subpixel of FIG. 2. FIG. 4 is a cross-sectional view taken along lines Q1-Q1′ and Q2-Q2′ of FIG. 3. FIG. 5 is a cross-sectional view taken along line Q3-Q3′ of FIG. 3. FIG. 6 is a cross-sectional view taken along lines Q4-Q4′ and Q5-Q5′ of FIG. 3.

FIG. 3 illustrates the arrangement of the electrodes 21 and 22, the light emitting elements 30 and contact electrodes CNE in the first subpixel PX1, and FIGS. 4 through 6 illustrate cross sections of the contact electrodes CNE according to the arrangement and shapes of the contact electrodes CNE. FIGS. 4 and 6 illustrate cross sections across one end and the other end of the light emitting elements 30 (30A and 30B) disposed in the first subpixel PX1.

Referring to FIGS. 3 through 6 in connection with FIG. 2, the display device 10 may include a first substrate 11 and a semiconductor layer, a plurality of conductive layers and a plurality of insulating layers disposed on the first substrate 11. The semiconductor layer, the conductive layers, and the insulating layers may constitute a circuit layer and a light emitting element layer of the display device 10.

Specifically, the first substrate 11 may be an insulating substrate. The first substrate 11 may be made of an insulating material such as glass, quartz, or polymer resin. In addition, the first substrate 11 may be a rigid substrate, but may also be a flexible substrate that can be bent, folded, rolled, etc.

A light blocking layer BML may be disposed on the first substrate 11. The light blocking layer BML is overlapped by an active layer ACT of a first transistor TR1 of the display device 10. The light blocking layer BML1 may include a light blocking material to prevent incidence of light to the active layer ACT of the first transistor. For example, the light blocking layer BML may be made of an opaque metal material that blocks transmission of light. However, the disclosure is not limited thereto. In some cases, the light blocking layer BML may be omitted.

A buffer layer 12 may be disposed on the entire surface of the light blocking layer BML and the first substrate 11. The buffer layer 12 may be formed on the first substrate 11 to protect the first transistors T1 of the pixels PX from moisture introduced through the first substrate 11 which is vulnerable to moisture penetration and may perform a surface planarization function. The buffer layer 12 may be composed of a plurality of inorganic layers stacked alternately. For example the buffer layer 12 may be a multilayer in which inorganic layers including at least any one of silicon oxide (SiOₓ), silicon nitride (SiNₓ), and silicon oxynitride (SiON) are alternately stacked or may be a single layer including the above materials.

The semiconductor layer is disposed on the buffer layer 12. The semiconductor layer may include the active layer ACT of the first transistor TR1. The active layer ACT may be partially overlapped by a gate electrode GE of a first gate conductive layer which will be described later.

Although only the first transistor TR1 among the transistors included in each subpixel PXn of the display device 10 is illustrated in the drawings, the disclosure is not limited thereto. The display device 10 may include more transistors. For example, the display device 10 may include two or three transistors by including one or more transistors in addition to the first transistor TR1 in each subpixel PXn.

The semiconductor layer may include polycrystalline silicon, monocrystalline silicon, an oxide semiconductor, or the like. When the semiconductor layer includes an oxide semiconductor each active layer ACT may include a plurality of conducting regions ACTa and ACTb and a channel region ACTc between them. The oxide semiconductor may be an oxide semiconductor containing indium (In). For example, the oxide semiconductor may be indium-tin oxide (ITO), indium-zinc oxide (IZO), indium-gallium oxide (IGO), indium-zinc-tin oxide (IZTO), indium-gallium-tin oxide (IGTO), indium-gallium-zinc oxide (IGZO), or indium-gallium-zinc-tin oxide (IGZTO).

In another embodiment, the semiconductor layer may include polycrystalline silicon. The polycrystalline silicon may be formed by crystalizing amorphous silicon. In this case, each conducting region of the active layer ACT may be a doped region doped with impurities.

A first gate insulating layer 13 is disposed on the semiconductor layer and the buffer layer 12. The first gate instating layer 13 may function as a gate insulating film of each transistor. The first gate insulating layer 13 may be a single layer including an inorganic material, for example, any one of silicon oxide (SiOₓ), silicon nitride (SiNₓ) and silicon oxynitride (SiON), or may be a double layer or a multilayer in which the above materials are stacked.

The first gate conductive layer is disposed on the first gate insulating layer 13. The first gate conductive layer may include the gate electrode GE of the first transistor T1 and a first capacitive electrode CSE1 of a storage capacitor. The gate electrode GE may overlap the channel region ACTc of the active layer ACT in a thickness direction. The first capacitive electrode CSE1 may be overlapped by a second capacitive electrode CSE2, which will be described later, in the thickness direction. In an embodiment, the first capacitive electrode CSE1 may be integrally connected to the gate electrode GE. The first capacitive electrode CSE1 may be overlapped by the second capacitive electrode CSE2 in the thickness direction, and the storage capacitor may be formed between them.

The first gate conductive layer may be, but is not limited to, a single layer or a multilayer made of any one or more of molybdenum (Mo), aluminum (Al), chromium (Cr), gold (Au), titanium (Ti), nickel (Ni), neodymium (Nd), copper (Cu), and alloys thereof.

A first protective layer 15 is disposed on the first gate conductive layer. The first protective layer 15 may cover the first gale conductive layer to protect the first gate conductive layer. The first protective layer 15 may be a single layer including an inorganic material, for example, any one of silicon oxide (SiOₓ), silicon nitride (SiNₓ) and silicon oxynitride (SiON), or may be a double layer or a multilayer in which the above materials are stacked.

A first data conductive layer is disposed on the first protective layer 15. The first data conductive layer may include a first source/drain electrode SD1 and a second source/drain electrode SD2 of the first transistor T1, a data line DTL, and the second capacitive electrode CSE2.

The source drain electrodes SD1 and SD2 of the first transistor T1 may respectively contact the doped regions ACTa and ACTb of the active layer ACT through contact holes penetrating a first interlayer insulating layer 17 and the first gate insulating layer 13. In addition, the first source/drain electrode SD1 of the first transistor T1 may be electrically connected to the light blocking layer BML through another contact hole.

The data line DTL may transmit a data signal to other transistors (not illustrated) included in the display device 10. Although not illustrated in the drawings, the data line DTL may be connected to source/drain electrodes of other transistors to transfer a signal transmitted to the data line DTL.

The second capacitive electrode CSE2 overlaps the first capacitive electrode CSE1 in the thickness direction. In an embodiment, the second capacitive electrode CSE2 may be integrally connected to the second source/drain electrode SD2.

The first data conductive layer may be, but is not limited to, a single layer or a multilayer made of any one or more of molybdenum (Mo), aluminum (Al), chromium (Cr), gold (Au), titanium (Ti), nickel (Ni), neodymium (Nd), copper (Cu), and alloys thereof.

The first interlayer insulating layer 17 is disposed on the first data conductive layer. The first interlayer insulating layer 17 may function as an insulating film between the first data conductive layer and other layers on the first data conductive layer. In the first interlayer insulating layer 17 may cover the first data conductive layer and protect the first data conductive layer. The first interlayer insulating layer 17 may be a single layer including an inorganic material for example, any one of silicon oxide (SiOₓ), silicon nitride (SiNₓ) and silicon oxynitride (SiON), or may be a double layer or a multilayer in which the above materials are stacked.

A second data conductive layer is disposed on the first interlayer insulating layer 17. The second data conductive layer may include a first voltage wiring VL1, a second voltage wiring VL2, and a first conductive pattern CDP. A high-potential voltage (or a first power supply voltage) supplied to the first transistor T1 may be applied to the first voltage wiring VL1, and a low-potential voltage (or a second power supply voltage) supplied to a second electrode 22 may be applied to the second voltage wiring VL2. In addition, an alignment signal needed to align the light emitting elements 30 may be transmitted to the second voltage wiring VL2 during a manufacturing process of the display device 10.

The first conductive pattern CDP may be connected to the second capacitive electrode CSE2 through a contact hole formed in the first inter layer insulating layer 17. The second capacitive electrode CSE2 may be integrated with the second source/drain electrode SD2 of the first transistor T1, and the first conductive pattern CDP may be electrically connected to the second source/drain electrode SD2. The first conductive pattern CDP may also contact a first electrode 21 to be described later, and the first transistor T1 may transfer the first power supply voltage received from the first voltage wiring VL1 to the first electrode 21 through the first conductive pattern CDP. Although the second data conductive layer includes one second voltage wiring VL2 and one first voltage wiring VL1 in the drawings, the disclosure is not limited thereto. The second data conductive layer may include more first voltage wirings VL1 and more second voltage wirings VL2.

The second data conductive layer may be, but is not limited to, a single layer or a multilayer made of any one or more of molybdenum (Mo), aluminum (Al), chromium (Cr), gold (Au), titanium (Ti), nickel (Ni), neodymium (Nd), copper (Cu), and alloys thereof.

A first planarization layer 19 is disposed on the second data conductive layer. The first planarization layer 19 may include an organic insulating material, for example, an organic material such as polyimide (PI) and may perform a surface planarization function.

A plurality of first banks BNL1, a plurality of electrodes 21 and 22, the light emitting elements 30, a plurality of contact electrodes CNE1 through CNE4, and the second bank layer BNL2 are disposed on the first planarization layer 19. In addition, a plurality of insulating layers PAS1 through P4S4 may be disposed on the first planarization layer 19.

The first banks BNL1 may be directly disposed on the first planarization layer 19. The first banks BNL1 may extend in the second direction DR2 in each subpixel PXn but may be disposed within the emission area EMA without extending to other subpixels PXn neighboring in the second direction DR2. In addition, the first banks BNL1 may be spaced apart from each other in the first direction DR1, and the light emitting elements 30 may be disposed between them. The first banks BNL1 may be disposed in each subpixel PXn to form linear patterns in the display area DPA of the display device 10. A length of each first bank BNL1 measured in the second direction DR2 may be greater than a length of each of the contact electrodes CNE1 and CNE2 to be described later. However, the disclosure is not limited thereto. Although two first banks BNL1 are illustrated in the drawings, the disclosure is not limited thereto. The number of the first banks BNL1 may be increased depending on the number of the electrodes 21 and 22 to be described later.

At least a portion of each of the first banks BNL1 may protrude from an upper surface of the first planarization layer 19. The protruding portion of each of the first banks BNL1 may have inclined side surfaces, and light emitted from the light emitting elements 30 may travel toward above the first planarization layer 19 after being reflected by the electrodes 21 and 22 disposed on the first banks BNL1. The first banks BNL1 may provide an area where the light emitting elements 30 are located while functioning as reflective barriers that reflect light emitted from the light emitting elements 30 in an upward direction. The side surfaces of the first banks BNL1 may be inclined in a linear shape. However, the disclosure is not limited thereto, and outer surfaces of the first banks BNL1 may also have a curved semi-circular or semi-elliptical shape. The first banks BNL1 may include an organic insulating material such as polyimide (PI), but the disclosure is not limited thereto.

The electrodes 21 and 22 are disposed on the first banks BNL1 and the first planarization layer 19. The electrodes 21 and 22 may include the first electrode 21 and the second electrode 22. The first electrode 21 and the second electrode 22 may extend in the second direction DR2 and may be spaced apart from each other in the first direction DR1.

Each of the first electrode 21 and the second electrode 22 may extend in the second direction DR2 in each subpixel PXn, but may be separated from another electrode 21 or 22 in the cutout area CBA. For example, the cutout area CBA may be disposed between the emission areas EMA of subpixels PXn neighboring in the second direction DR2, and the first electrode 21 and the second electrode 22 may be separated, in the cutout area CBA, from another first electrode 21 and another second electrode 22 disposed in a subpixel PXn neighboring in the second direction DR2. However, the disclosure is not limited thereto, and some electrodes 21 and 22 may not be separated. For each subpixel PXn but may extend beyond the subpixels PXn neighboring in the second direction DR2, or only one of the first electrode 21 and the second electrode 22 may be separated.

The first electrode 21 may be electrically connected to the first transistor T1 through a first contact hole CT1, and the second electrode 22 may be electrically connected to the second voltage wiring VL2 through a second contact hole CT2. For example, the first electrode 21 may contact the first conductive pattern CDP through the first contact hole CT1 penetrating the first planarization layer 19 in a portion of the second hank BNL2 which extends in the first direction DR1. The second electrode 22 may also contact the second voltage wiring VL2 through the second contact hole CT2 penetrating the first planarization layer 19 in the portion of the second bank BNL2 which extends in the first direction DR1. However, the disclosure is not limited thereto. In another embodiment, the first contact hole CT1 and the second contact hole CT2 may be disposed in the emission area EMA surrounded by the second bank BNL2 so as not to overlap the second bank BNL2.

Although one first electrode 21 and one second electrode 22 are disposed in each subpixel PXn in the drawings, the disclosure is not limited thereto, and more first electrodes 21 and more second electrodes 22 may be disposed in each subpixel PXn. In addition, the firm electrode 21 and the second electrode 22 disposed in each subpixel PXn may not necessarily extend in one direction and may be disposed in various structures. For example, the first electrode 21 and the second electrode 22 may be partially curved or bent, or any one of the first electrode 21 and the second electrode 22 may surround the other electrode.

The first electrode 21 and the second electrode 22 may be disposed on the first banks BNL1, respectively. The first electrode 21 and the second electrode 22 may be formed to have greater widths than the first banks BNL1, respectively. For example, the first electrode 21 and the second electrode 22 may cover the outer surfaces of the first banks BNL1, respectively. The first electrode 21 and the second electrode 22 may be disposed on the side surfaces of the first banks BNL1, respectively and a distance between the first electrode 21 and the second electrode 22 may be smaller than a distance between the first banks BNL1. In addition, at least a portion of each of the first electrode 21 and the second electrode 22 may be directly disposed on the first planarization layer 19 so that they lie in the same plane. However, the disclosure is not limited thereto. In some cases, the widths of the electrodes 21 and 22 may be smaller than those of the first banks BNL1, respectively. However, each of the electrodes 21 and 22 may cover at least one side surface of a first bank BNL1 to reflect light emitted from the light emitting elements 30.

Each of the electrodes 21 and 22 may include a transparent conductive material. For example, each of the electrodes 21 and 22 may include a material such as indium-tin oxide (ITO), indium-zinc oxide (IZO), or indium-tin-zinc oxide (ITZO). However, the disclosure is not limited thereto, and each of the electrodes 21 and 22 may include a conductive material having high reflectivity. For example, each of the electrodes 21 and 22 may include a metal such as silver (Ag), copper (Cu) or aluminum (Al) as a material having high reflectivity. In this case, each of the electrodes 21 and 22 may reflect light, which travels toward the side surfaces of the first banks BNL1 after being emitted from the light emitting elements 30, toward above each subpixel PXn.

However, the disclosure is not limited thereto, and each of the electrodes 21 and 22 may also have a structure in which a transparent conductive material and a metal layer having high reflectivity are each stacked in one or more layers or may also be formed as a single layer including the transparent conductive material and the metal layer. For example, each of the electrodes 21 and 22 may have a stacked structure of ITO/Ag/ITO, ITO/Ag/IZO or ITO/Ag/ITZO-IZO or may be an alloy containing aluminum (Al), nickel (Ni), or lanthanum (La).

The electrodes 21 and 22 may be electrically connected to the light emitting elements 30, and a predetermined voltage may be applied to the electrodes 21 and 22 so that the light emitting elements 30 can emit light. For example, the electrodes 21 and 22 may be electrically connected to the light emitting elements 30 through the contact electrodes CNE to be described later and may transmit received electrical signals to the light emitting elements 30 through the contact electrodes CNE.

Any one of the first electrode 21 and the second electrode 22 may be electrically connected to anodes of the light emitting elements 30, and the other may be electrically connected to cathodes of the light emitting elements 30. However, the disclosure is not limited thereto, and the opposite case may also be true.

In addition, each of the electrodes 21 and 22 may be utilized to form an electric field in each subpixel PXn so as to align the light emitting elements 30. The light emitting elements 30 may be arranged between the first electrode 21 and the second electrode 22 by the electric field formed on the first electrode 21 and the second electrode 22. The light emitting elements 30 of the display device 10 may be sprayed onto the electrodes 21 and 22 through an inkjet printing process. When ink including the light emitting elements 30 is sprayed onto the electrodes 21 and 22, an alignment signal is transmitted to the electrodes 21 and 22 to generate an electric field. The light emitting elements 30 dispersed in the ink may be aligned on the electrodes 21 and 22 by a dielectrophoretic force applied by the electric field generated on the electrodes 21 and 22.

A first insulating layer PAS1 is disposed on the first planarization layer 19. The first insulating layer PAS1 may cover the first banks BNL1, the first electrode 21, and the second electrode 22. In an embodiment, the first insulating layer PAS1 may include openings OP1 and OP2 partially exposing the first electrode 21 and the second electrode 22. The first insulating layer PAS1 may include a first opening OP1 exposing a portion of an upper surface of the first electrode 21 and a second opening OP2 exposing a portion of an upper surface of the second electrode 22. The first opening OP1 and the second opening OP2 may partially expose portions of the electrodes 21 and 22 which are disposed on upper surfaces of the first banks BNL1, respectively. Some of the contact electrodes CNE, which will be described later, may respectively contact the electrodes 21 and 22 exposed through the openings OP1 and OP2.

The first insulating layer PAS1 may be stepped such that a portion of an upper surface of the first insulating layer PAS1 is recessed between the first electrode 21 and the second electrode 22. For example, since the first insulating layer PAS1 covers the first electrode 21 and the second electrode 22, the upper surface of the first insulating layer PAS1 may be stepped according to the shapes of the electrodes 21 and 22 disposed under the first insulating layer PAS1. However the disclosure is not limited thereto. The first insulating layer PAS1 may protect the first electrode 21 and the second electrode 22 while insulating them from each other. In addition, the first insulating layer PAS1 may prevent direct contact of the light emitting demons 30 on the first insulating layer PAS1 with other members, and thus, prevent damage to the light emitting elements 30 on the first insulating layer PAS1.

The second bank BNL2 may be disposed on the first insulating layer PAS1. The second bank BNL2 may include portions extending in the first direction DR1 and the second direction DR2 in plan view and may be disposed in a grid pattern over the entire display area DPA. The second bank BNL2 may be disposed at the boundary of each subpixel PXn to separate neighboring subpixels PXn.

In addition, the second bank BNL2 may surround the emission area EMA and the cutout area CBA disposed in each subpixel PXn to separate them. The first electrode 21 and the second electrode 22 may extend in the second direction DR2 to cross a portion of the second bank BNL2 which extends in the first direction DR1. A portion of the second bank BNL2 which extends in the second direction DR2 may have a greater width between the emission areas EMA than between the cutout areas CBA. Accordingly, the distance between the cutout areas CBA may be smaller than the distance between the emission areas EMA.

The second bank BNL2 may be formed to have a greater height than the first banks BNL1. The second bank BNL2 may prevent ink from overflowing to adjacent subpixels PXn in an inkjet printing process during the manufacturing process of the display device 10. Accordingly, the second bank BNL2 may separate inks in which different light emitting elements 30 are dispersed for different subpixels PXn so as to prevent mixing of the inks with each other. Like the first banks BNL1, the second bank BNL2 may include, but is not limited to, polyimide (PI).

The light emitting elements 30 may be disposed on the first insulating layer PAS1. The light emitting elements 30 may be spaced apart from each other along the second direction DR2 in which each of the electrodes 21 and 22 extends and may be aligned substantially parallel to each other. The light emitting elements 30 may extend in one direction, and the direction in which the electrodes 21 and 22 extend and the direction in which the light emitting elements 30 extend may be substantially perpendicular to each other. However, the disclosure is not limited thereto, and the light emitting elements 30 may also extend in a direction not perpendicular but oblique to the direction in which the electrodes 21 and 22 extend.

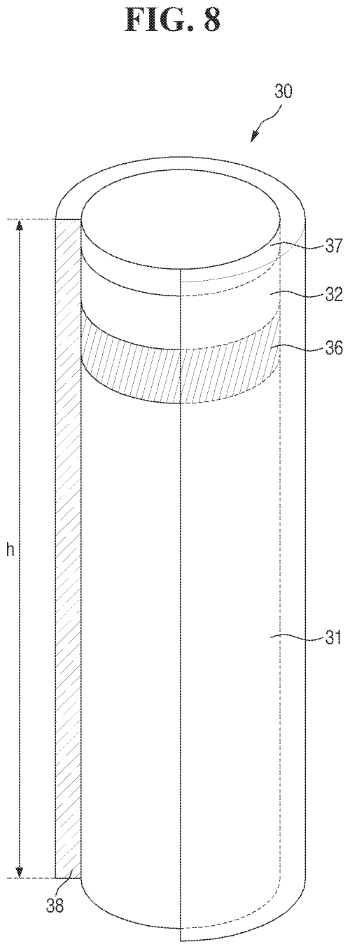

The light emitting elements 30 disposed in the subpixels PXn may include light emitting layers 36 (see FIG. 8) including different materials to emit light of different wavelength hands. Accordingly, light of the first color, light of the second color, and light of the third color may be output from the first subpixel PX1, the second subpixel PX2, and the third subpixel PX3, respectively. However, the disclosure is not limited thereto, and the subpixels PXn may also include the light emitting elements 30 of the same type to emit light of substantially the same color.

Both ends of each light emitting element 30 may be respectively disposed on the electrodes 21 and 22 between the first banks BNL1. A length by which the light emitting elements 30 extend may be greater than the distance between the first electrode 21 and the second electrode 22, and both ends of each light emitting element 30 may be disposed on the first electrode 21 and the second electrode 22, respectively. For example, one end of each light emitting element 30 may be disposed on the first electrode 21, and the other end may be disposed on the second electrode 22.

Each of the light emitting elements 30 may include a plurality of layers located in a direction perpendicular to an upper surface of the first substrate 11 or the first planarization layer 19. The direction in which the light emitting elements 30 extend may be parallel to the upper surface of the first planarization layer 19, and the semiconductor layers included in each of the light emitting elements 30 may be sequentially located along a direction parallel to the upper surface of the first planarization layer 19. However, the disclosure is not limited thereto. When each of the light emitting elements 30 has a different structure, the layers may also be located in a direction perpendicular to the upper surface of the first planarization layer 19.

Both ends of each light emitting element 30 may contact the contact electrodes CNE, respectively. For example, an insulating film 38 (see FIG. 8) may not be formed on end surfaces of each light emitting element 30 in the direction in which the light emitting elements 30 extend, thereby exposing some of the semiconductor layers. Thus, the exposed semiconductor layers may contact the contact electrodes CNE. However the disclosure is not limited thereto, and at least a portion of the insulating film 38 of each light emitting element 30 may be removed to partially expose side surfaces of both ends of the semiconductor layers. The exposed side surfaces of the semiconductor layers may directly contact the contact electrodes CNE.

According to an embodiment, the light emitting elements 30 may include light emitting elements 30A and 30B having both ends in contact with different contact electrodes CNE. The light emitting elements 30 may include first light emitting elements 30A and second light entitling elements 30B which may be electrically connected through contact electrodes CNE connected to each other. First ends of the first light emitting elements 30A and the second light emitting elements 30B may contact different contact electrodes CNE, and second ends of the first light emitting elements 30A and the first ends of the second light emitting elements 30B may contact the contact electrodes CNE connected to each other. The first light emitting elements 30A and the second light emitting elements 30B may be connected in series to each other through the contact electrodes CNE, and the luminance per unit area of each subpixel PXn may be improved. This will be described in more detail later.

A second insulating layer PAS2 may be disposed on the light emitting elements 30. The second insulating layer PAS2 may be partially disposed on the first insulating layer PAS1, the first electrode 21, the second electrode 22, and the fight emitting elements 30. For example, the second insulating layer PAS2 may be disposed on the entire surface of the first insulating layer PAS1 in an area surrounded by the second bank BNL2, except for both ends of each light emitting element 30 and portions of the upper surfaces of the electrodes 21 and 22 on which the contact electrodes CNE are disposed. The second insulating layer PAS2 may be placed to cover the light emitting elements 30, the electrodes 21 and 22 and the first insulating layer PAS1 during the manufacturing process of the display device 10 and then may be removed to expose both ends of the light emitting elements 30. A portion of the second insulating layer PAS2 may cover the light emitting elements 30 while exposing both ends of the light emitting elements 30. A portion of the second insulating layer PAS2 which is disposed on the light emitting elements 30 may extend in the second direction DR2 on the first insulating layer PAS1 in plan view to form a linear or island-shaped pattern in each subpixel PXn. The second insulating layer PAS2 may protect the light emitting elements 30 while anchoring the light emitting elements 30 in the manufacturing process of the display device 10. In addition, in some embodiments, a portion of the second insulating layer PAS2 may fill a space between the light emitting elements 30 and the first insulating layer PAS1.

In addition, the second insulating layer PAS2 may partially cover an outer side of each of the electrodes 21 and 22. The contact electrodes CNE may be partially disposed in portions where the second insulating layer PAS2 is not disposed. However, the disclosure is not limited thereto, and the second insulating layer PAS2 may also be disposed only between the electrodes 21 and 22 to anchor the light emitting elements 30 and may be removed in other areas.

A plurality of contact electrodes CNE and a third insulating layer PAS3 may be disposed on the second insulating layer PAS2.

The contact electrodes CNE may extend in one direction and may be disposed on the electrodes 21 and 22, respectively. The contact electrodes CNE may include a first contact electrode CNE1 and a fourth contact electrode CNE4 disposed on the first electrode 21 and a second contact electrode CNE2 and a third contact electrode CNE3 disposed on the second electrode 22. The contact electrodes CNE may be spaced apart from each other or may face each other. For example, the first contact electrode CNE1 and the fourth contact electrode CNE4 may be spaced apart from each other in the second direction DR2 on the first electrode 21, and the second contact electrode CNE2 and the third contact electrode CNE3 may be spaced apart from each other in the second direction DR2 on the second electrode 22. In addition, the first contact electrode CNE1 and the third contact electrode CNE3 may face each other in the first direction DR1, and the second contact electrode CNE2 and the fourth contact electrode CNE4 may also face each other in the first direction DR1. Each of the contact electrodes CNE may form a stripe pattern in the emission area EMA of each subpixel PXn.

Each of the contact electrodes CNE may contact the light emitting elements 30. The first contact electrode CNE1 and the fourth contact electrode CNE4 may contact one end of each light emitting element 30, and the second contact electrode CNE2 and the third contact electrode CNE3 may contact the other end of each light emitting element 30. As described above, the semiconductor layers may be exposed on both end surfaces of each light emitting element 30 in the direction in which the light emitting elements 30 extend, and the contact electrodes CNE may be electrically connected to the semiconductor layers of each light emitting element 30 by contacting the semiconductor layers. Respective sides of the contact electrodes CNE which contact both ends of the light emitting elements 30 may be disposed on the second insulating layer PAS2.

Widths of the contact electrodes CNE measured in a direction may be smaller than widths of the electrodes 21 and 22 measured in the direction, respectively. The contact electrodes CNE may respectively contact one end and the other end of each light emitting element 30 and may partially cover the upper surfaces of the first electrode 21 and the second electrode 22. However, the disclosure is not limited thereto, and the contact electrodes CNE may also be wider than the electrodes 21 and 22 to cover both sides of the electrodes 21 and 22.

The contact electrodes CNE may include a transparent conductive material such as ITO, IZO, ITZO, or aluminum (Al). Light emitted from the light emitting elements 30 may pass through the contact electrodes CNE to travel toward the electrodes 21 and 22. However, the disclosure is not limited thereto.

According to an embodiment, the contact electrodes CNE may include first-type contact electrodes CNE#1 contacting the electrodes 21 and 22 through openings OP of the first insulating layer PAS1 and a second-type contact electrode CNE#2 not contacting the electrodes 21 and 22 and only contacting the light emitting elements 30. In addition, the second-type contact electrode CNE#2 may include portions disposed on the electrodes 21 and 22 but not contacting the electrodes 21 and 22 and may further include an electrode connection portion BE connecting the portions disposed on the electrodes 21 and 22. The first-type contact electrodes CNE#1 and the second-type contact electrode CNE#2 may contact the light emitting elements 30 but may be distinguished from each other according to whether they contact the electrodes 21 and 22 and whether they are connected to the electrode connection portion BE.

For example, each of the first contact electrode CNE1 and the second contact electrode CNE2 may be a first-type contact electrode CNE#1. The first contact electrode CNE1 may cover the first opening OP1 and contact the first electrode 21 through the first opening OP1, and the second contact electrode CNE2 may cover the second opening CP2 and contact the second electrode 22 through the second opening OP2. The first contact electrode CNE1 and the second contact electrode CNE2 may extend in one direction and may be disposed on the electrodes 21 and 22 and directly connected to the electrodes 21 and 22.

The second-type contact electrode CNE#2 includes contact portions CP1 and CP2 respectively disposed on the electrodes 21 and 22 to contact the light emitting elements 30 and the electrode connection portion BE connecting the contact portions CP1 and CP2 to each other. The third contact electrode CNE3 and the fourth contact electrode CNE4 may be the contact portions CP1 and CP2 of the second-type contact electrode CNE#2. The third contact electrode CNE3 may be a first contact portion CP1 spaced apart from the second contact electrode CNE2 and facing the first contact electrode CNE1, and the fourth contact electrode CNE4 may be a second contact portion CP2 spaced apart from the first contact electrode CNE1 and facing the second contact electrode CNE2. The electrode connection portion BE may connect the first contact portion CP1 and the second contact portion CP2 or the third contact electrode CNE3 and the fourth contact electrode CNE4, and the third contact electrode CNE3 and the fourth contact electrode CNE4 may be electrically connected to each other through the electrode connection portion BE.

Each of the light emitting elements 30 may have one end disposed on the first electrode 21 and the other end disposed on the second electrode 22. Both ends of each light emitting element 30 may contact the first and second-type contact electrodes CNE#1 and CNE#2, respectively, and some of the light emitting elements 30 may be electrically connected to each other through the second-type contact electrode CNE#2. According to an embodiment, the light emitting elements 30 may include the first light emitting elements 30A having the first ends in contact with the first contact electrode CNE1 and the second ends in contact with the third contact electrode CNE3 and the second light emitting elements 30B having the first ends in contact with the fourth contact electrode CNE4 and second ends in contact with the second contact electrode CNE2.

The first ends of the first light emitting elements 30A and the second ends of the second light emitting elements 30B contact the first-type contact electrodes CNE#1, respectively. The first ends of the first light emitting elements 30A contact the first contact electrode CNE1, and the second ends of the second light emitting elements 30B contact the second contact electrode CNE2. The first ends of the first light emitting elements 30A and the second ends of the second light emitting elements 30B may be electrically connected to the electrodes 21 and 22 through the first-type contact electrodes CNE#1, respectively.

The second ends of the first light emitting elements 30A and the first ends of the second light emitting elements 30B contact the second-type contact electrode CNE#2. The second ends of the first light emitting elements 30A contact the third contact electrode CNE3, and the first ends of the second light emitting elements 30B contact the fourth contact electrode CNE4. Since the third contact electrode CNE3 and the fourth contact electrode CNE4 are connected to each other through the electrode connection portion BE, the second ends of the first light emitting elements 30A and the first ends of the second light emitting elements 30B may be electrically connected to each other through the second-type contact electrode CNE#2. The first electrode 21 and the second electrode 22 may be electrically connected to the first transistor T1 and the second voltage wiring VL2 under them through the first contact hole CT1 and the second contact hole CT2, respectively, and may receive electrical signals from the first transistor T1 and the second voltage wiring VL2. The electrical signals may flow through the first-type contact electrodes CNE#1, the first light emitting elements 30A, the second light emitting elements 30B, and the second-type contact electrode CNE#2. Since the first light emitting elements 30A and the second light emitting elements SOB are electrically connected to each other through the second-type contact electrode CNE#2, they may be connected in series to each other. When certain light emitting elements 30 are disposed in each subpixel PXn, if some of the light emitting elements 30 are connected in series to each other, the amount of light emitted from the light emitting elements 30 may increase. In the display device 10, a plurality of light emitting elements 30 may be connected in series in each subpixel PXn to increase luminance per unit subpixel. In addition, since the light emitting elements 30 are connected in series, even if some of the contact electrodes CNE short-circuit, the light emitting elements 30 contacting other contact electrodes CNE may emit light. For example, when the first contact electrode CNE1 and the third contact electrode CNE3 in contact with the first light emitting elements 30A are directly connected to each other to short-circuit, even if the first light emitting elements 30A do not emit light, the second light emitting elements 30B may emit light. The display device 10 can improve the luminance of each subpixel PXn while minimizing light emission failure in which a corresponding subpixel PXn does not completely emit light.

In an embodiment, the electrode connection portion BE and the contact portions CP1 and CP2 or the third contact electrode CNE3 and the fourth contact electrode CNE4 may be integrated with each other and disposed on the same layer, and the first-type contact electrodes CNE#1 and the second-type contact electrode CNE#2 may be disposed on different layers. The first contact electrode CNE1 and the second contact electrode CNE2 of the first-type contact electrodes CNE#1 are formed in the same process but spaced apart from each other. The third contact electrode CNE3, the fourth contact electrode CNE4, and the electrode connection portion BE of the second-type contact electrode CNE#2 are formed to be connected to each other in the same process to form an integrated contact electrode. However, the disclosure is not limited thereto, and the electrode connection portion BE may also be formed in a separate process and connected to the contact portions CP1 and CP2.

The third insulating layer PAS3 may be disposed between the first-type contact electrodes CNE#1 and the second-type contact electrode CNE#2. The third insulating layer PAS3 may also be disposed on the first-type contact electrodes CNE#1 and the second insulating layer PAS2 excluding areas where the contact portions CP1 and CP2 of the second-type contact electrode CNE#2 are disposed. The second insulating layer PAS2 may be disposed on the entire surface of the first insulating layer PAS1 except for portions where the contact electrodes CNE are disposed on the electrodes 21 and 22, and the third insulating layer PAS3 may be disposed on the entire surface of the first insulating layer PAS1 except for portions where the second-type contact electrodes CNE#2 are disposed on the electrodes 21 and 22. The third insulating layer PAS3 may insulate the first-type contact electrodes CNE#1 from the second-type contact electrode CNE#2 so that they do not directly contact each other. That is, in an embodiment, the first-type contact electrodes CNE#1 and the second-type contact electrode CNE#2 may be disposed on different layers. The first-type contact electrodes CNE#1 may be directly disposed on the second insulating layer PAS2, and the second-type contact electrode CNE#2 may be directly disposed on the third insulating layer PAS3. However, the first-type contact electrodes CNE#1 and the second-type contact electrode CNE#2 may also be directly disposed on the first insulating layer PAS1 in an area where the second insulating layer PAS2 and the third insulating layer PAS3 are not disposed and where both ends of the light emitting elements 30 are exposed.

In addition, the second insulating layer PAS2 and the third insulating layer PAS3 may be disposed in an area where the light emitting elements 30 are not disposed or between the electrodes 21 and 22 and the second bank BNL2, so that the electrode connection portion BE is disposed on the second insulating layer PAS2 or the third insulating layer PAS3. Since the electrode connection portion BE is disposed on the third insulating layer PAS3, it may be insulated from the first-type contact electrodes CNE#1 by the third insulating layer PAS3. However, the disclosure is not limited thereto, and the third insulating layer PAS3 may also be omitted, and the second-type contact electrode CNE#2 may be directly disposed on the second insulating layer PAS2.

In addition, according to an embodiment, the electrode connection portion BE of the second-type contact electrode CNE#2 may be spaced apart from an outer side of a first-type contact electrode CNE#1 and may surround the outer side. The electrode connection portion BE may include a first extension portion EP1 extending in the second direction DR2 and connected to the third contact electrode CNE3 and a second extension portion EP2 extending in the first direction DR1 and having a side connected to the first extension portion EP1 and the other side connected to the fourth contact electrode CNE4. The first extension portion EP1 of the electrode connection portion BE may be spaced apart from a long side of an outer side of the second contact electrode CNE2, and the second extension portion EP2 may be spaced apart from a short side of the outer side of the second contact electrode CNE2. Accordingly, the electrode connection portion BE may surround the outer side of the second contact electrode CNE2. The first extension portion EPI of the electrode connection portion BE may not overlap the second electrode 22.

The electrode connection portion BE of the second-type contact electrode CNE#2 may connect the contact portions CP1 and CP2 or the third contact electrode CNE3 and the fourth contact electrode CNE4 via an area where the light emitting elements 30 are not disposed. An area where the contact electrodes CNE are spaced apart from each other is a portion of the emission area EMA of each subpixel PXn in which the light emitting elements 30 can be disposed. Thus, the electrode connection portion BE is placed not to cross the area where the contact electrodes CNE are spaced apart from each other. The electrode connection portion BE may surround an outer side of a first-type contact electrode CNE#1 and may be disposed between an electrode 21 or 22 and the second bank BNL2. Since the electrode connection portion BE is disposed only in the area where the light emitting elements 30 are not disposed, it is possible to connect some light emitting elements 30 in series while maintaining the number of the light emitting elements 30 disposed in each subpixel PXn. In the display device 10, the placement of the electrode connection portion BE is designed to secure a sufficient area in which the light emitting elements 30 of each subpixel PXn are disposed and to connect the light emitting elements 30 in series. Therefore, even if the area occupied by each subpixel PXn is small, it is possible to improve luminance while maintaining the size of each subpixel PXn.

According to an embodiment, distances DC1 and DC2 between the electrode connection portion BE and a first-type contact electrode CNE#1, for example, the second contact electrode CNE2, may be equal to or smaller than a distance between the contact electrodes CNE. The first-type contact electrodes CNE#1 and the second-type contact electrode CNE#2 may not be directly connected to each other but may be electrically connected to each other through the light emitting elements 30. In one subpixel PXn, the electrode connection portion BE surrounds the outer side of the second contact electrode CNE2 while being spaced apart from the second contact electrode CNE2 by a predetermined distance or more. The distance DC1 between the first extension portion EP1 of the electrode connection portion BE and a long side of the outer side of the second contact electrode CNE2 and the distance DC2 between the second extension portion EP2 and a short side of the outer side of the second contact electrode CNE2 may be large enough to prevent them from directly contacting each other. The distances DC1 and DC2 may be equal to distances between the first-type contact electrodes CNE#1 and the contact portions CP1 and CP2 of the second-type contact electrode CNE#2, but may also be smaller within the range in which they may not be connected to each other.

The third insulating layer PASS may be disposed between the first-type contact electrodes CNE#1 and the second-type contact electrode CNE#2 to insulate them from each other. However, the third insulating layer PAS3 may also be omitted as described above. In this case, the first-type contact electrodes CNE#1 and the second-type contact electrode CNE#2 may be disposed on the same layer, and the electrode connection portion BE may be spaced apart from a first-type contact electrode CNE#1 by predetermined distances (DC1 and DC2) within the range in which it is not directly connected to the first-type contact electrode CNE#1.

Although two first-type contact electrodes CNE#1 and one second-type contact electrode CNE#2 are disposed in one subpixel PXn in the drawings, the disclosure is not limited thereto. One first contact electrode CNE1 in contact with the first electrode 21 and one second contact electrode CNE2 in contact with the second electrode 22 may be disposed as the first-type contact electrodes CNE#1, but the second-type contact electrode CNE#2 may also include a greater number of the contact portions CP1 and CP2 and the electrode connection portions BE. Accordingly, the number of the light emitting elements 30 connected in series in each subpixel PXn may increase, and the luminance of each subpixel PXn may be further improved.

A fourth insulating layer PAS4 may be disposed on the entire surface of the first substrate 11. The fourth insulating layer PAS4 may function to protect members on the first substrate 11 from the external environment.

Each of the first insulating layer PAS1, the second insulating layer PAS2, the third insulating layer PAS3, and the fourth insulating layer PAS4 described above may include an inorganic insulating material or an organic insulating material. For example, the first insulating layer PAS1, the second insulating layer PAS2, the third insulating layer PAS3, and the fourth Insulating layer PAS4 may include an inorganic insulating material such as silicon oxide (SiOₓ), silicon nitride (SiNₓ), silicon oxynitride (SiOₓN_{y}), aluminum oxide (AlOₓ), or aluminum nitride (AlNₓ). Alternatively, the first insulating layer PAS1, the second insulating layer PAS2, the third insulating layer PAS3, and the fourth insulating layer PAS4 may include an organic insulating material such as acrylic resin, epoxy resin, phenolic resin, polyamide resin, polyimide resin, unsaturated polyester resin, polyphenylene resin, polyphenylene sulfide resin, benzocyclobutene, cardo resin, siloxane resin, silsesquioxane resin, polymethyl methacrylate, polycarbonate, or polymethyl methacrylate-polycarbonate synthetic resin. However, the disclosure is not limited thereto.

A first-type contact electrode CNE#1 and a contact portion CP1 or CP2 of the second-type contact electrode CNE#2 or the first contact electrode CNE1 and the third contact electrode CNE3 may be spaced apart from the fourth contact electrode CNE4 and the second contact electrode CNE2 in the second direction DR2, respectively, and the light emitting elements 30 may also be disposed between them. These light emitting elements 30 may be disposed on the electrodes 21 and 22 with both ends not in contact with the contact electrodes CNE and may remain as light emitting elements 30 not emitting light in each subpixel PXn.

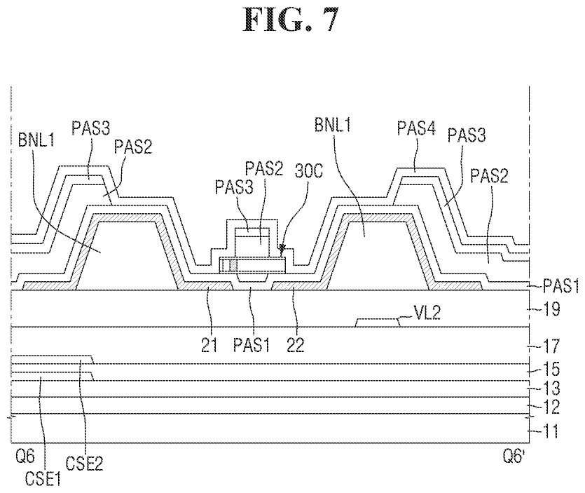

FIG. 7 is a cross-sectional view taken along line Q6-Q6′ of FIG. 3.

Referring to FIG. 7, the light emitting elements 30 according to an embodiment may further include a third light emitting element 30C having both ends not in contact with the contact electrodes CNE. Both ends of the third light emitting element 30C may be disposed on the first electrode 21 and the second electrode 22, but the contact electrodes CNE may not be disposed on the electrodes 21 and 22 on which both ends of the third light emitting element 30C are disposed. The first-type contact electrodes CNE#1 and the contact portions CP1 and CP2 of the second-type contact electrode CNE#2 may be spaced apart from each other in the second direction DR2 on the electrodes 21 and 22, and the light emitting elements 30 may also be disposed in an area between them. The light emitting elements include the third light emitting element 30C not electrically connected to the contact electrodes CNE, and both ends of the third light emitting element 30C may be exposed by the second insulating layer PAS2 and the third insulating layer PAS3. Both ends of the third light emitting element 30C may directly contact the fourth insulating layer PAS4 disposed on them. The display device 10 may include the third light emitting element 30C not emitting light. However, even if each subpixel PXn includes some lost light emitting elements 30 such as the third light emitting element 30C, since the first light emitting elements 30A and the second light emitting elements 30B are connected in series, sufficient luminance can be provided. In addition, the third light emitting element 30C may be surrounded by the second insulating layer PAS2, and its position may be anchored during the manufacturing process of the display device 10. Although the third light emitting element 30C is not connected to the contact electrodes CNE, it may not deviate from its position to act as a foreign substance in a subsequent process, and the display device 10 may have sufficient luminance even if it includes some lost light emitting elements 30.

The display device 10 according to the embodiment may improve luminance per unit area by connecting some light emitting elements 30 in each subpixel PXn in series to each other. In addition, since the electrode connection portion BE of the second-type contact electrode CNE#2 which connects the light emitting elements 30 in series is placed to pass through an area where the light emitting elements 30 are not disposed, it is possible to connect the light emitting elements 30 in series while maintaining the size of each subpixel PXn and the number of the light emitting elements 30.

FIG. 8 is a schematic view of a light emitting element according to an embodiment.

The light emitting element 30 may be a light emitting diode. Specifically, the light emitting element 30 may be an inorganic light emitting diode having a size of micrometers or nanometers and made of an inorganic material. When an electric field is formed in a specific direction between two electrodes facing each other, the inorganic light emitting diode may be aligned between the two electrodes in which polarities are formed. The light emitting element 30 may be aligned between two electrodes by the electric field formed on the electrodes.

The light emitting element 30 according to the embodiment may extend in one direction. The light emitting element 30 may be shaped like a cylinder, a rod, a wire, a tube, or the like. However, the shape of the light emitting element 30 is not limited thereto, and the light emitting element 30 may also have various shapes including polygonal prisms, such as a cube, a rectangular parallelepiped or a hexagonal prism, and a shape extending in a direction and having a partially inclined outer surface. A plurality of semiconductors included in the light emitting element 30 which will be described later may be sequentially arranged or stacked along the one direction.

The light emitting element 30 may include a semiconductor layer doped with impurities of any conductivity type (e.g., a p type or an n type). The semiconductor layer may receive an electrical signal from an external power source and emit light of a specific wavelength band.

Referring to FIG. 8, the light emitting element 30 may include a first semiconductor layer 31, a second semiconductor layer 32, a light emitting layer 36, an electrode layer 37, and an insulating film 38.

The first semiconductor layer 31 may be an n-type semiconductor. If the light emitting element 30 emits light in a blue wavelength band, the first semiconductor layer 31 may include a semiconductor material having a chemical formula of AlₓGa_{y}In_{1-x-y}N (0≤x≤1, 0≤y≤1, 0≤x+y≤1). For example, the semiconductor material included in the first semiconductor layer 31 may be any one or more of n-type doped AlGaInN, GaN, AlGaN, InGaN, AlN, and InN. The first semiconductor layer 31 may be doped with an n-type dopant, and the n-type dopant may be Si, Ge, or Sn. For example, the first semiconductor layer 31 may be n-GaN doped with n-type Si. A length of the first semiconductor layer 31 may be in a range of, but not limited to, 1.5 to 5 μm.

The second semiconductor layer 32 is disposed on the light emitting layer 36 to be described later. The second semiconductor layer 32 may be a p-type semiconductor. If the light emitting element 30 emits light in a blue or green wavelength band, the second semiconductor layer 32 may include a semiconductor material having a chemical formula of AlₓGa_{y}In_{1-x-y}N (0≤x≤1, 0≤y≤1, 0≤x+y≤1). For example, the semiconductor material included in the second semiconductor layer 32 may be any one or more of p-type doped AlGaInN, GaN, AlGaN, InGaN, AlN, and InN. The second semiconductor layer 32 may be doped with a p-type dopant, and the p-type dopant may be Mg, Zn, Ca, Se, or Ba. For example, the second semiconductor layer 32 may be p-GaN doped with p-type Mg. A length of the second semiconductor layer 32 may be in a range of, but not limited to, 0.05 to 0.10 μm.

Although each of the first semiconductor layer 31 and the second semiconductor layer 32 is composed of one layer in the drawing, the disclosure is not limited thereto. Each of the first semiconductor layer 31 and the second semiconductor layer 32 may also include more layers, for example, may further include a clad layer or a tensile strain barrier reducing (TSBR) layer depending on the material of the light emitting layer 36.

The light emitting layer 36 is disposed between the first semiconductor layer 31 and the second semiconductor layer 32. The light emitting layer 36 may include a material having a single or multiple quantum well structure. When the light emitting layer 36 includes a material having a multiple quantum well structure, it may have a structure in which a plurality of quantum layers and a plurality of well layers are alternately stacked. The light emitting layer 36 may emit light through combination of electron-hole pairs according to electrical signals received though the first semiconductor layer 31 and the second semiconductor layer 32. If the light emitting layer 36 emits light in the blue wavelength band, it may include a material such as AlGaN or AlGaInN. In particular, when the light emitting layer 36 has a multiple quantum well structure in which a quantum layer and a well layer are alternately stacked, the quantum layer may include a material such as AlGaN or AlGaInN, and the well layer may include a material such as GaN or AlInN. For example, the light emitting layer 36 may include AlGaInN as a quantum layer and AlInN as a well layer to emit blue light whose central wavelength band is in a range of 450 to 495 nm as described above.

However, the disclosure is not limited thereto and the light emitting layer 36 may also have a structure in which a semiconductor material having a large band gap energy and a semiconductor material having a small band gap energy are alternately stacked or may include different group 3 to 5 semiconductor materials depending on the wavelength band of light that it emits. Light emitted from the light emitting layer 36 is not limited to light in the blue wavelength band. In some cases, the light emitting layer 36 may emit light in a red or green wavelength band. A length of the light emitting layer 36 may be in a range of, but not limited to, 0.05 to 0.10 μm.

Light emitted from the light emitting layer 36 may be radiated not only through an outer surface of the light emitting element 30 in a longitudinal direction, but also through both side surfaces. The direction of light emitted from the light emitting layer 36 is not limited to one direction.

The electrode layer 37 may be an ohmic contact electrode. However, the disclosure is not limited thereto, and the electrode layer 37 may also be a Schottky contact electrode. The light emitting element 30 may include at least one electrode layer 37. Although the light emitting element 30 includes one electrode layer 37 in FIG. 8, the disclosure is not limited thereto. In some cases, the light emitting element 30 may include additional electrode layers 37, or the electrode layer 37 may be omitted. The following description of the light emitting element 30 may apply equally even when the light emitting element 30 includes a different number of electrode layers 37 or further includes another structure.

When the light emitting element 30 is electrically connected to electrodes or contact electrodes in the display device 10 according to the embodiment, the electrode layer 37 may reduce the resistance between the tight emitting element 30 and the electrodes or the contact electrodes. The electrode layer 37 may include a conductive metal. For example, the electrode layer 37 may include at least any one of aluminum (Al), titanium (Ti), indium (In), gold (Au), silver (Ag), indium tin oxide (ITO), indium zinc oxide (IZO), and indium tin zinc oxide (ITZO). In addition, the electrode layer 37 may include an n-type or p-type doped semiconductor material. The electrode layer 37 may include the same material or different materials, but the disclosure is not limited thereto.

The insulating film 38 surrounds outer surfaces of the semiconductor layers and the electrode layer described above. For example, the insulating film 38 may surround an outer surface of at least the light emitting layer 36 and extend in the direction in which the light emitting element 30 extends. The insulating film 38 may protect the above members. For example, the insulating film 38 may surround side surfaces of the above members but may expose both ends of the light emitting element 30 in the longitudinal direction.

In the drawing, the insulating film 38 extends in the longitudinal direction of the light emitting element 30 to cover from side surfaces of the first semiconductor layer 31 to side surfaces of the electrode layer 37. However, the disclosure is not limited thereto, and the insulating film 38 may cover outer surfaces of the light emitting layer 36 and only some semiconductor layers or may cover only a portion of an outer surface of the electrode layer 37 to partially expose the outer surface of the electrode layer 37. In addition, an upper surface of the insulating film 38 may be rounded in cross section in an area adjacent to at least one end of the light emitting element 30.

A thickness of the insulating film 38 may be in a range of, but not limited to, 10 nm to 1.0 μm. The thickness of the insulating film 38 may be, for example, about 40 nm.

The insulating film 38 may include an insulating material such as silicon oxide (SiOₓ), silicon nitride (SiNₓ), silicon oxynitride (SiOₓN_{y}), aluminum nitride (AlNₓ), or aluminum oxide (AlOₓ). Accordingly, it can present an electrical short circuit that may occur when the light emitting layer 36 directly contacts an electrode that transmits an electrical signal to the light emitting element 30. In addition, since the insulating film 38 protects the outer surface of the light emitting element 30 including the light emitting layer 36, a reduction in luminous efficiency can be prevented.

In addition, an outer surface of the insulating film 38 may be treated. The light emitting element 30 dispersed in a predetermined ink may be sprayed onto electrodes and then aligned. Here, the surface of the insulating film 38 may be hydrophobic or hydrophilic-treated so that the light emitting element 30 is kept separate in the ink without being agglomerated with other adjacent light emitting elements 30.

A length h of the light emitting element 30 may be in a range of 1 to 10 μm or 2 to 6 μm and may be, for example, in a range of 3 to 5 μm. In addition, a diameter of the light emitting element 30 may be in a range of 30 to 700 nm, and an aspect ratio of the light emitting element 30 may be 1.2 to 100. However, the disclosure is not limited thereto, and a plurality of light emitting elements 30 included in the display device 10 may also have different diameters according to a difference in composition of the light emitting layer 36. The diameter of the light emitting element 30 may be for example, about 500 nm.

Hereinafter, other embodiments of the display device 10 will be described with reference to other drawings.

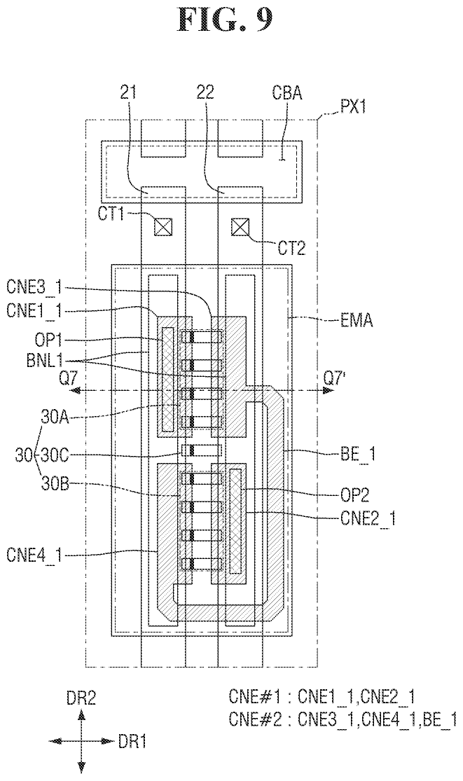

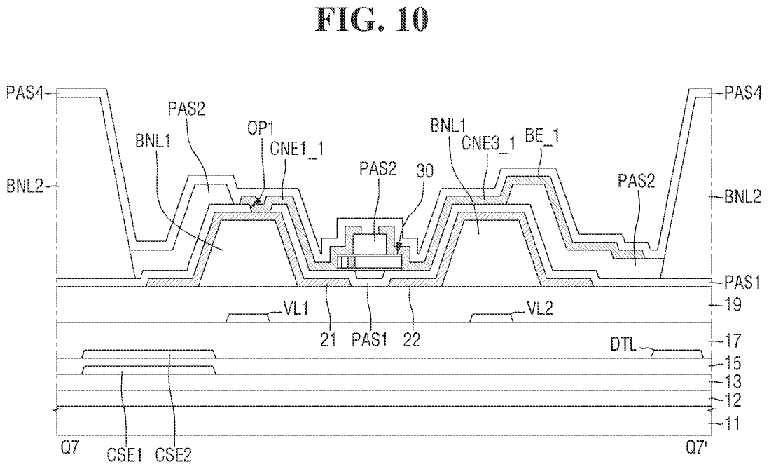

FIG. 9 is a plan view of a subpixel of a display device according to another embodiment. FIG. 10 is a cross-sectional view taken along line Q7-Q7′ of FIG. 9.

Referring to FIGS. 9 and 10, in the display device 10, a third insulating layer PAS3 may be omitted. First-type contact electrodes CNE#1 and a second-type contact electrode CNE#2 of the display device 10 may each be directly disposed on a first insulating layer PAS1 or a second insulating layer PAS2 and may be disposed on the same layer. The current embodiment is different from the embodiment of FIGS. 4 through 6 in that the third insulating layer PAS3 is omitted. Hereinafter, any redundant description will be omitted, and differences will be mainly described.

In an embodiment, the third insulating layer PAS3 may be omitted, and the first-type contact electrodes CNE#1 and the second-type contact electrode CNE#2 may be directly disposed on the first insulating layer PAS1 and the second insulating layer PAS2. A plurality of contact electrodes CNE may be simultaneously formed in the same process and may be disposed on the same layer. The first-type contact electrodes CNE#1 and contact portions CP1 and CP2 of the second-type contact electrode CNE#2 may be spaced apart from each other on the second insulating layer PAS2 disposed on light emitting elements 30. A first contact electrode CNE1_1 and a third contact electrode CNE3_1 as well as a second contact electrode CNE2_1 and a fourth contact electrode CNE4_1 are spaced apart from each other on the second insulating layer PAS2 and are not directly connected to each other. An electrode connection portion BE_1 is also directly disposed on the second insulating layer PAS2. The electrode connection portion BE_1 surrounds an outer side of the second contact electrode CNE2_1. among the first-type contact electrodes CNE#1, but is spaced apart from the outer side of the second contact electrode CNE2_1 by a predetermined distance. Therefore, the electrode connection portion BE_1 may not be directly connected to the second contact electrode CNE2_1.

In the display device 10, even if the third insulating layer PAS3 is omitted, the first-type contact electrodes CNE#1 and the second-type contact electrode CNE#2 are spaced apart from each other by a predetermined distance. In particular, since the electrode connection portion BE_1 surrounding any one of the first-type contact electrodes CNE#1 is spaced apart from the first-type contact electrode CNE#1 by predetermined distances DC1 and DC2, they may not be directly connected to each other. First light emitting elements 30A and second light emitting elements 30B may be electrically connected in series through the second-type contact electrode CNE#2.

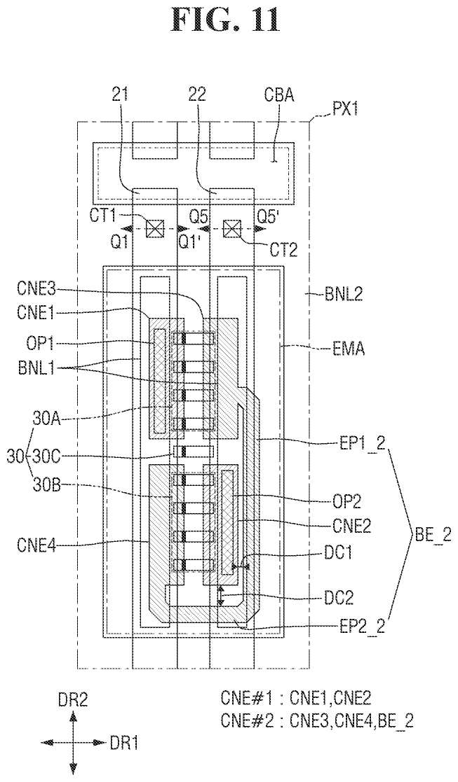

FIG. 11 is a plan view of a subpixel of a display device according to another embodiment.

Referring to FIG. 11, in the display device 10 according to the embodiment, a distance DC1 between a first extension portion EP1_2 of an electrode connection portion BE_2 and a second contact electrode CNE2 may be smaller than a distance DC2 between a second extension portion EP2 and the second contact electrode CNE2. The first extension portion EP1_2 of the electrode connection portion BE_2 may overlap an outer side of a second electrode 22 in the thickness direction. The current embodiment is different from the embodiment of FIG. 3 in that the distance DC1 between the first extension portion EP1_2 of the electrode connection portion BE_2 and the second contact electrode CNE2 is smaller.

Since a third insulating layer PAS3 is disposed between first-type contact electrodes CNE#1 and a second-type contact electrode CNE#2 as described above, the first-type contact electrodes CNE#1 and the second-type contact electrode CNE#2 may not directly contact each other. The electrode connection portion BE_2 may surround an outer side of the second contact electrode CNE2 but may not directly contact the second contact electrode CNE2 even if the distances DC1 and DC2 between them become smaller. In addition, even if the third insulating layer PAS3 is omitted, the electrode connection portion BE_2 may be spaced apart from the second contact electrode CNE2 to such an extent that it does not direct contact the second contact electrode CNE2. In the display device 10, since the electrode connection portion BE_2 bypasses the second contact electrode CNE2 at a minimum distance from the second contact electrode CNE2, the area occupied by an emission area EMA of each subpixel PXn can be further minimized. Accordingly, a greater number of subpixels PXn per unit area can be disposed in the display device 10, and an ultra-high resolution display device can be realized.

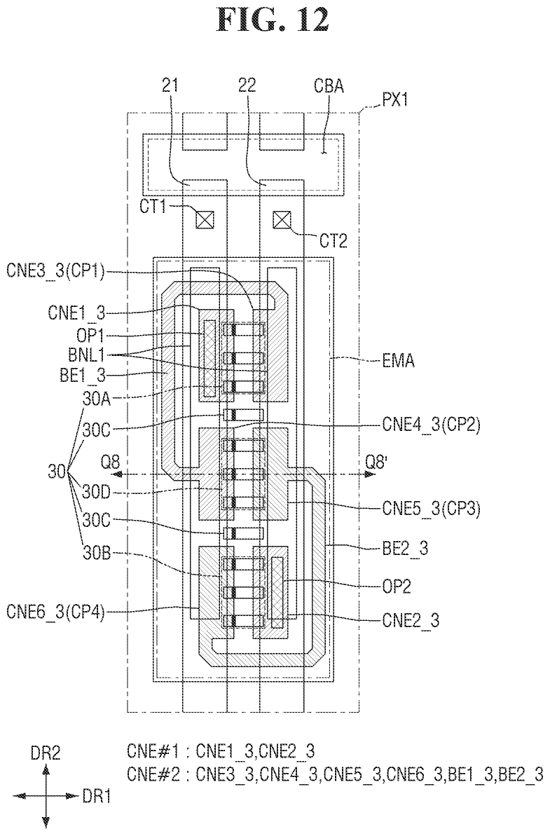

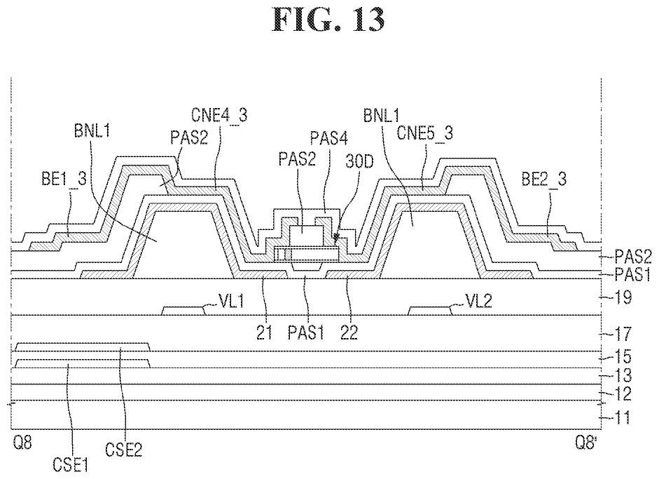

FIG. 12 is a plan view of a subpixel of a display device according to another embodiment. FIG. 13 is a cross-sectional view taken along line Q8-Q8′ of FIG. 12. FIG. 13 illustrates a cross section across both ends of a light emitting element 30 which contact second-type contact electrodes CNE#2. In addition, FIGS. 12 and 13 illustrate an embodiment in which a greater number of second-type contact electrodes CNE#2 are disposed in the display device 10 of FIG. 9 from which the third insulating layer PAS3 is omitted.

Referring to FIGS. 12 and 13, the display device 10 according to the embodiment may include a greater number of second-type contact electrodes CNE#2 to connect more light emitting elements 30 in series in each subpixel PXn. Each subpixel PXn may further include fourth light emitting elements 30D connected in series between first light emitting elements 30A and second light emitting elements 30B. In each subpixel PXn, the first light emitting elements 30A, the fourth light emitting elements 30D, and the second light emitting elements 30B may be connected in series to further improve the luminance of each subpixel PXn.

As in the embodiment of FIG. 9, first-type contact electrodes CNE#1 include a first contact electrode CNE1_3 disposed on a first electrode 21 and a second contact electrode CNE2_3 disposed on a second electrode 22. The first contact electrode CNE1_3 and the second contact electrode CNE2_3 may contact the electrodes 21 and 22 through openings OP1 and OP2 of a first insulating layer PAS1, respectively. The second-type contact electrodes CNE#2 may include a third contact electrode CNE3_3, a fourth contact electrode CNE4_3 and a first electrode connection portion BE1_3 connecting them and may further include a fifth contact electrode CNE5_3, a sixth contact electrode CNE6_3 and a second electrode connection portion BE2_3 connecting them. Since the arrangement of the first-type contact electrodes CNE#1 is the same as that described above with reference to the embodiment of FIG. 9, the second-type contact electrodes CNE#2 will be described below.

The third contact electrode CNE3_3 is disposed on the second electrode 22 to face the first contact electrode CNE1_3. The fourth contact electrode CNE4_3 is disposed on the first electrode 21 and spaced apart from the first contact electrode CNE1_3 in the second direction DR2. The arrangement of the third contact electrode CNE3_3 and the fourth contact electrode CNE4_3 may be substantially the same as that of the embodiment of FIG. 3. However, the first electrode connection portion BE1_3 connecting the third contact electrode CNE3_3 and the fourth contact electrode CNE4_3 may surround an outer wall of the first contact electrode CNE1_3 among the first-type contact electrodes CNE#1.

The fifth contact electrode CNE5_3 is disposed on the second electrode 22 between the third contact electrode CNE3_3 and the second contact electrode CNE2_3. The fifth contact electrode CNE5_3 may be spaced apart from each of the third contact electrode CNE3_3 and the second contact electrode CNE2_3 in the second direction DR2 and may face the fourth contact electrode CNE4_3 in the first direction DR1. The sixth contact electrode CNE6_3 is disposed on the first electrode 21 and spaced apart from the fourth contact electrode CNF 4 3 in the second direction DR2. The sixth contact electrode CNE6_3 may face the second contact electrode CNE2_3 in the first direction DR1. The fifth contact electrode CNE5_3 may be a third contact portion CP3 of a second-type contact electrode CNE#2, and the sixth contact electrode CNE6_3 may be a fourth contact portion CP4 of the second-type contact electrode CNE#2. The second electrode connection portion BE2_3 connecting the fifth contact electrode CNE5_3 and the sixth contact electrode CNE6_3 may surround an outer wall of the second contact electrode CNE2_3 which is a first-type contact electrode CNE#1.

One end of each first light emitting element 30A contacts the first contact electrode CNE1_3, and the other end contacts the third contact electrode CNE3_3. One end of each second light emitting element 30B contacts the sixth contact electrode CNE6_3, and the other end contacts the second contact electrode CNE2_3. One end of each fourth light emitting element 30D contacts the fourth contact electrode CNE4_3, and the other end contacts the fifth contact electrode CNE5_3. The first light emitting elements 30A and the fourth light emitting elements 30D as well as the fourth light emitting elements 30D and the second light emitting elements 30B may be connected in series to each other through the second-type contact electrodes CNE#2. In the display device 10 according to the current embodiment, the light emitting elements 30 of each subpixel PXn can be connected in multiple series, and the luminance of each subpixel PXn can be further improved.

The first electrode 21 and the second electrode 22 may not necessarily extend in one direction. In some embodiments, the electrodes 21 and 22 of the display device 10 may include portions extending with different widths and a portion extending in a different direction.

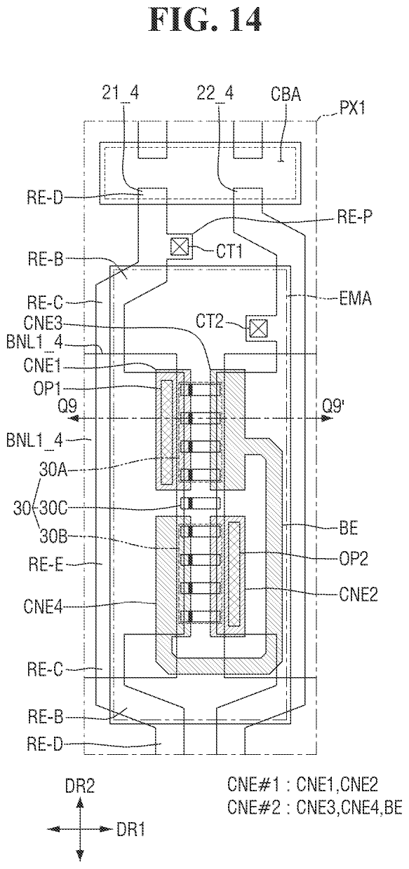

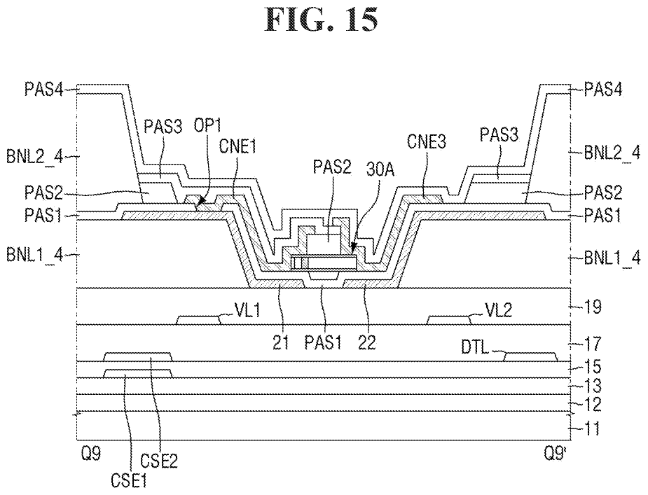

FIG. 14 is a plan view of a subpixel of a display device according to another embodiment. FIG. 15 is a cross-sectional view taken along line Q9-Q9′ of FIG. 14.

Referring to FIGS. 14 and 15, each of electrodes 21_4 and 22_4 of the display device 10 according to the embodiment may include a widened portion RE-E extending in the second direction DR2 and having a greater width than other portions, bent portions RE-B extending in directions inclined from the first direction DR1 and the second direction DR2, and connection portions RE-C connecting the bent portions RE-B and the widened portion RE-E. Each of the electrodes 21_4 and 22_4 may generally extend in the second direction DR2, but may have a greater width in a portion or may be bent in directions inclined from the second direction DR2. A first electrode 21_4 and a second electrode 22_4 may be disposed in a symmetrical structure with respect to an area between them. Hereinafter, any redundant description will be omitted, and the shape of the first electrode 21_4 will be mainly described.

The first electrode 214 may include the widened portion RE-E having a greater width than other portions. The widened portion RE-E may be disposed on each first bank BNL1_4 in an emission area EMA of each subpixel PXn and may extend in the second direction DR2. Light emitting elements 30 may be disposed on the widened portions RE-E of the first electrode 21_4 and the second electrode 22_4. In addition, contact electrodes CNE may be disposed on the widened portion RE-E of each of the electrodes 21_4 and 22_4, but their widths may be smaller than that of the widened portion RE-E. First-type contact electrodes CNE#1 may cover openings OP1 and OP2 partially exposing upper surfaces of the widened portions RE-E of the electrodes 21_4 and 22_4 and thus may contact the widened portions RE-E. Widened portions of a second-type contact electrode CNE#2 are spaced apart from the first-type contact electrodes CNE#1 in the second direction DR2 on the widened portions RE-E, and an electrode connection portion BE is spaced apart from a second contact electrode CNE2 on the widened portion RE-E of the second electrode 22_4.

The connection portions RE-C may be respectively connected to both sides of each widened portion RE-E in the second direction DR2. The connection portions RE-C1 and RE-C2 may be connected to each widened portion RE-E and may be disposed over the emission area EMA of each subpixel PXn and a second bank BNL2.

Widths of the connection portions RE-C may be smaller than the widths of the extension portions RE-E. One side of each connection portion RE-C which extends in the second direction DR2 may be coil nearly connected to one side of a widened portion RE-E which extends in the second direction DR2. For example, among both sides of each of a widened portion RE-E and a connection portion RE-C, one side of the widened portion RE-E and one side of the connection portion RE-C located outside a center of the emission area EMA may extend and may be connected to each other. Accordingly, a distance DE1 between the widened portions RE-E of the first electrode 21_4 and the second electrode 22_4 may be smaller than a distance DE2 between the connection portions RE-C.

The bent portions RE-B are connected to the connection portions RE-C. The bent portions RE-B connected to the connection portions RE-C may be bent in directions inclined from the second direction DR2, for example, toward a center of each subpixel PXn. A shortest distance DE3 between the bent portions RE-B of the first electrode 21_4 and the second electrode 22_4 may be smaller than the distance DE2 between the connection portions RE-C. However, the shortest distance DE3 between the bent portions RE-B may be greater than the distance DE1 between the widened portions RE-E.

A length of a connection portion RE-C connected to an upper side of the widened portion RE-E of the first electrode 21_4 may be smaller than a length of a connection portion RE-C connected to an upper side of the widened portion RE-E of the second electrode 22_4. Accordingly, the upper bent portion RE-B of the first electrode 21_4 and the upper bent portion RE-B of the second electrode 22_4 may be staggered with each other. On the other hand, connection portions RE-C connected to lower sides of the widened portions RE-E of the electrodes 21_4 and 22_4 may have the same length, and the lower bent portions RE-B may be disposed symmetrically to each other.

In addition, a fragment portion RE-D remaining after the electrodes 21_4 are separated in a cutout area CBA may be formed at an end of each upper bent portion RE-B. The fragment portion RE-D may be a portion remaining after the electrodes 21_4 or 22_4 of subpixels PXn neighboring in the second direction DR2 are separated in the cutout area CBA.

The first electrode 21_4 may have a contact portion RE-P disposed between the upper bent portion RE-B and the fragment portion R&D and having a relatively large width. The second electrode 22_4 may have a contact portion RE-P formed in the upper connection portion RE-C. In the contact portions RE-P, a first contact hole CT1 and a second contact hole CT2 of the first electrode 21_1 and the second electrode 22_4 may be formed.

The embodiment of FIG. 14 is different from the embodiment of FIG. 2 in that the first electrode 21_4 and the second electrode 22_4 include the widened portions RE-E, the connection portions RE-C1 and RE-C2 and the bent portions RE-B1 and RE-B2 and are symmetrically disposed with respect to the center of each subpixel PXn. However, the disclosure is not limited thereto. In some cases, the first electrode 21_4 and the second electrode 22_4 may have different shapes.

In addition, each first bank BNL1_4 may have a greater width and may be disposed across a boundary between subpixels PXn neighboring in the first direction DR1. A first bank BNL1_4 may be disposed in the emission area EMA of each subpixel PXn and across the boundary between the subpixels PXn. Accordingly, a portion of the second bank BNL2 which extends in the second direction DR2 may be partially disposed on the first bank BNL1_4. In one subpixel PXn, two first banks BNL1_4 may be partially disposed. The widened portions RE-E of the electrodes 21_4 and 22_4 may be disposed on the first banks BNL1_4, and the contact electrodes CNE may contact the light emitting elements 30 disposed between the first banks BNL1_4 and may be disposed on the widened portions RE-E of the electrodes 21_4 and 22_4.

The contact electrodes CNE may be disposed on inclined side surfaces of the electrodes 21 and 22 and the first banks BNL1 along a step formed by them. In particular, when the contact electrodes CNE are disposed on the widened portions RE-E of the electrodes 21_4 and 22_4 as in the embodiment of FIG. 14, a slope due to the first banks BNL1_4 and the widened portions RE-E may be large at upper or lower corners of the widened portions RE-E. When the contact electrodes CNE are disposed at corners of the widened portions RE-E, materials that form the contact electrodes CNE may be connected by a step formed by the first banks BNL1_4 and electrodes under the contact electrodes CNE. To prevent this, in the display device 10, widths of the contact electrodes CNE may be reduced at the corners of the widened portions RE-E.

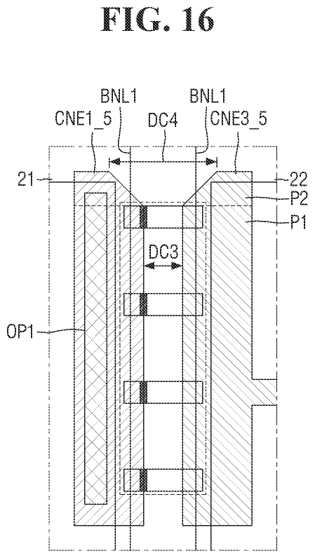

FIG. 16 schematically illustrates contact electrodes of a display device according to another embodiment. FIG. 16 is an enlarged view of a first contact electrode CNE1_5 and a third contact electrode CNE3_5 having different shapes in the display device 10 of FIG. 14.

Referring to FIG. 16, each contact electrode CNE may include a first portion P1 and a second portion P2 having a smaller width than the first portion P1. As for a distance between the contact electrodes CNE facing each other in the first direction DR1, a distance DC4 between the second portions P2 may be greater than a distance DC3 between the first portions P1. For example, each of the first contact electrode CNE1_5 and the third contact electrode CNE3_5 may include the first portion P1 having a relatively large width and the second portion P2 having a smaller width than the first portion P1. Each of the first contact electrode CNE1_5 and the third contact electrode CNE3_5 may, on the whole, have the same width as the first portion P1, but a portion (or the second portion P2) disposed on a corner of an electrode 21 or 22 and a first bank BNL1 may have a smaller width.

The first banks BNL1 may protrude from an upper surface of a first planarization layer 19, and each side of the first banks BNL1 may be inclined in cross section. Upper and lateral sides of each first bank BNL1 when seen in plan view may be inclined in cross section, and at a corner where they meet, may be more inclined than other portions of each side. When seen in plan view, widened portions RE-E of the electrodes 21 and 22 disposed on the first banks BNL1 may also be further stepped at a corner where upper and lateral sides meet.

In a patterning process for forming the contact electrodes CNE, materials that form the contact electrodes CNE must be spaced apart from each other by a certain distance. However, the materials may not be spaced apart from each other by a desired distance on a corner where upper and lateral sides of each widened portion RE-E meet due to a step formed under the corner. In this case, the materials of the contact electrodes CNE facing each other, for example, the first contact electrode CNE1_5 and the third contact electrode CNE3_5 may be partially connected to each other. In the display device 10, each of the contact electrodes CNE may be formed to have a small width in a portion where a large step is formed under the contact electrode CNE. Accordingly, this can prevent different contact electrodes CNE from being directly connected to each other.

In an embodiment, as for the distance between the contact electrodes CNE, the distance DC3 between the first portions P1 may be smaller than the distance DC4 between the second portions P2. For example, a side of the second portion P2 of each contact electrode CNE which faces another contact electrode CNE may be inclined such that the width of the contact electrode CNE is reduced toward the upper side. That is, each contact electrode CNE may be chamfered in a portion where a large step is formed under the contact electrode CNE and may be prevented from being directly connected to another contact electrode CNE in the portion.

In concluding the detailed description, those skilled in the art will appreciate that many variations and modifications can be made to the preferred embodiments without substantially departing from the principles of the invention. Therefore, the disclosed preferred embodiments of the invention are used in a generic and descriptive sense only and not for purposes of limitation.

1. A display device comprising:
a first substrate;
a first electrode and a second electrode extending in a first direction on the first substrate and spaced apart from each other in a second direction;
a plurality of light emitting elements disposed on the first electrode and the second electrode; and
a plurality of contact electrodes disposed on the first electrode or the second electrode and contacting the light emitting elements,
wherein the contact electrodes comprise a first contact electrode disposed on the first electrode,
a second contact electrode disposed on the second electrode,
a third contact electrode spaced apart from the second contact electrode in the first direction and facing the first contact electrode in the second direction, and
a fourth contact electrode spaced apart from the first contact electrode in the first direction and facing the second contact electrode in the second direction, and
the display device comprises an electrode connection portion connected to the third contact electrode and the fourth contact electrode and surrounding the second contact electrode.

2. The display device of claim 1, wherein the electrode connection portion is integrated with the third contact electrode and the fourth contact electrode.

3. The display device of claim 1, further comprising a first insulating layer disposed on the first substrate to cover the first electrode and the second electrode and comprising a first opening exposing a portion of an upper surface of the first electrode and a second opening exposing a portion of an upper surface of the second electrode,
wherein the light emitting elements are disposed on the first insulating layer.

4. The display device of claim 3, further comprising a second insulating layer disposed on the first insulating layer and the light emitting elements and exposing both ends of each light emitting element and portions of the first insulating layer on which the contact electrodes are disposed.

5. The display device of claim 3, wherein the first contact electrode, the second contact electrode, the third contact electrode and the fourth contact electrode are directly disposed on the first insulating layer, and
at least a portion of the electrode connection portion is disposed on the second insulating layer.

6. The display device of claim 2, further comprising a third insulating layer covering the first contact electrode and the second contact electrode,
wherein at least a portion of each of the third contact electrode, the fourth contact electrode, and
the electrode connection portion is disposed on the third insulating layer.

7. The display device of claim 1, wherein the light emitting elements comprise a first light emitting element having an end in contact with the first contact electrode and the other end in contact with the third contact electrode, and
a second light emitting element having an end in contact with the fourth contact electrode and the other end in contact with the second contact electrode.

8. The display device of claim 1, wherein the light emitting elements further comprise a third light emitting element having both ends not in contact with the contact electrodes.

9. The display device of claim 3, wherein the first contact electrode covers the first opening to contact the first electrode,
the second contact electrode covers the second opening to contact the second electrode, and
the third contact electrode and the fourth contact electrode are disposed on the first insulating layer not to contact the first electrode and the second electrode.

10. The display device of claim 1, wherein the electrode connection portion comprises a first extension portion extending in the first direction and connected to the third contact electrode, and a second extension portion extending in the second direction and having a side connected to the first extension portion and the other side connected to the fourth contact electrode,
wherein the first extension portion is spaced apart from a long side of an outer side of the second contact electrode, and
the second extension portion is spaced apart from a short side of the outer side of the second contact electrode.

11. The display device of claim 10, wherein a distance between the long side of the second contact electrode and the first extension portion of the electrode connection portion is equal to or smaller than a distance between the second contact electrode and the fourth contact electrode.

12. The display device of claim 11, wherein the first extension portion of the electrode connection portion partially overlaps the second electrode in a thickness direction.

13. The display device of claim 1, wherein each of the contact electrodes comprises a first portion and a second portion having a smaller width than the first portion, and
a distance between the contact electrodes facing each other in the second direction is greater between the second portions than between the first portions.

14. A display device comprising:
a first substrate;
a first electrode and a second electrode extending in a first direction on the first substrate and spaced apart from each other in a second direction;
a first insulating layer disposed on the first substrate and comprising an opening that exposes a portion of the first electrode or the second electrode;
a plurality of light emitting elements disposed on the first insulating layer and having both ends disposed on the first electrode and the second electrode, respectively;
a plurality of first-type contact electrodes disposed on the first electrode or the second electrode and contacting the light emitting elements and the first electrode or the second electrode; and
a second-type contact electrode contacting the light emitting elements and not contacting the first electrode and the second electrode,
wherein the second-type contact electrode comprises a plurality of contact portions disposed on the first electrode or the second electrode but spaced apart from the first-type contact electrodes and an electrode connection portion connecting the contact portions,
wherein the electrode connection portion is spaced apart from an outer side of any one of the first-type contact electrodes and surrounds the outer side.

15. The display device of claim 14, wherein the first-type contact electrodes comprise a first contact electrode disposed on the first electrode and contacting the first electrode through a first opening exposing a portion of an upper surface of the first electrode, and
a second contact electrode disposed on the second electrode and contacting the second electrode through a second opening exposing a portion of an upper surface of the second electrode, and
the second-type contact electrode comprises a first contact portion disposed on the second electrode and spaced apart from the second contact electrode,
a second contact portion disposed on the first electrode and spaced apart from the first contact electrode, and
a first electrode connection portion connecting the first contact portion and the second contact portion.

16. The display device of claim 15, wherein the first electrode connection portion surrounds an outer side of the second contact electrode.

17. The display device of claim 16, wherein the light emitting elements comprise a first light emitting element having an end in contact with the first contact electrode and the other end in contact with the first contact portion and a second light emitting element having an end in contact with the second contact portion and the other end in contact with the second contact electrode.

18. The display device of claim 15, wherein the first contact portion faces the first contact electrode,
the second contact portion is spaced apart from the first contact electrode in the first direction,
the first electrode connection portion surrounds an outer side of the first contact electrode, and
the second-type contact electrode further comprises a third contact portion disposed between the second contact electrode and the first contact portion to face the second contact portion,
a fourth contact portion spaced apart from the second contact portion in the first direction to face the second contact electrode, and
a second electrode connection portion connecting the third contact portion and the fourth contact portion and surrounding the outer side of the second contact electrode.

19. The display device of claim 14, further comprising a second insulating layer disposed on the first insulating layer and the light emitting elements and exposing both ends of each light emitting element and portions of the first insulating layer on which the contact electrodes are disposed,
wherein the first-type contact electrodes and the contact portions of the second-type contact electrode are disposed on the same layer.

20. The display device of claim 10, wherein the electrode connection portion of the second-type contact electrode is directly disposed on the second insulating layer.
